(19) United States
(12) Patent Application Publication
(10) Pub. No.: US 2025/0048887 A1
(43) Pub. Date: Feb. 6, 2025

(54) DISPLAY DEVICE

(71) Applicant: SAMSUNG DISPLAY CO., LTD., YONGIN-SI (KR)

(72) Inventors: SUNG SIK YUN, Yongin-si (KR); HEE SANG PARK, Yongin-si (KR); JU YEON SEO, Yongin-si (KR); JAE EUN YU, Yongin-si (KR)

(21) Appl. No.: 18/603,280

(22) Filed: Mar. 13, 2024

(30) Foreign Application Priority Data
Aug. 4, 2023 (KR) 10-2023-0101990

(51) Int. Cl. H10K 59/80; H10K 59/131; H10K 59/40

(52) U.S. Cl. CPC H10K 59/873; H10K 59/131; H10K 59/40

(57) ABSTRACT

A display device includes a substrate, a circuit layer, an element layer, and a sealing layer. The substrate includes a main area and a sub-area. The main area includes a display area and a non-display area. The non-display area includes a dam area in which one or more dam portions surrounding the display area are arranged, and a junction area surrounding the dam area. The sub-area includes a bending area, a first sub-area, and a second sub-area. The circuit layer includes a power supply line. The power supply line includes a main supply portion disposed in the non-display area, a sub-connection portion extending from the main supply portion to the sub-area, and a branch portion disposed in the junction area and protruding from one side of the sub-connection portion. The branch portion is spaced apart from a bank covering a bending hole of the bending area.

### CROSS-REFERENCE TO RELATED APPLICATION

This application claims priority from Korean Patent Application No. 10-2023-0101990, filed on Aug. 4, 2023, in the Korean Intellectual Property Office, and all the benefits accruing therefrom under 35 U.S.C. 119, the contents of which in its entirety are herein incorporated by reference.

### BACKGROUND

### 1. Technical Field

One or more embodiments described herein relate to a display device.

### 2. Description of the Related Art

The demand for display devices continues to increase. For example, display devices are used in smartphones, digital cameras, laptop computers, navigation devices, smart televisions, and other types of electronic devices.

Flat panel display devices include liquid crystal display devices, field emission display devices, and light emitting display devices. Examples of light emitting display devices include organic light emitting display devices (which include organic light emitting elements), inorganic light emitting display devices (which include inorganic light emitting elements that use an inorganic semiconductor), and a micro or nano light emitting display devices which include micro or nano light emitting elements.

Organic light emitting display devices generate images using light emitting elements, each of which includes a light emitting layer made of an organic light emitting material. Because organic light emitting display devices display images using self-light emitting elements, organic light emitting display devices may demonstrate relatively superior performance in terms of power consumption, response speed, emission efficiency, luminance, and wide viewing angle compared to other display devices.

A display device as described above may include a display area for displaying an image and a non-display area surrounding the display area. Light emitting areas that emit light with respective luminance and color may be arranged in the display area.

Structurally, the display device may include a substrate including the display area and the non-display area, a circuit layer disposed on the substrate and including pixel drivers corresponding to respective light emitting areas, a light emitting element layer disposed on the circuit layer and including light emitting elements corresponding to respective light emitting areas, and a sealing layer disposed on the light emitting element layer. The sealing layer may be bonded to an inorganic insulating material of the circuit layer in the non-display area to seal the light emitting element layer. Such a sealing layer may block permeation of oxygen or moisture, thereby preventing rapid deterioration of the organic light emitting material of the light emitting element layer.

The circuit layer may include insulating layers disposed between conductive layers. The conductive layers lines electrically connected to pixel drivers. Because the conductive layers of the circuit layer are made of a metal material, some of the insulating layers of the circuit layer adjacent to the substrate may include an inorganic insulating material. In addition, considering uniformity of a direction in which the light emitting elements of the light emitting element layer emit light, some of the insulating layers of the circuit layer adjacent to the light emitting element layer may include an organic insulating material having a relatively thick thickness.

### SUMMARY

In accordance with one or more embodiments, a display device is provided which is capable of improving quality and lifespan by reducing the lifting defect or corrosion defect of the lines disposed in the junction area.

According to an aspect of the present disclosure, there is provided a display device comprises a substrate; a circuit layer disposed on the substrate; an element layer disposed on the circuit layer; and a sealing layer disposed on the element layer. The substrate includes a main area and a sub-area protruding from one side of the main area. The main area includes a display area in which light emitting areas are arranged, and a non-display area disposed around the display area. The non-display area includes a dam area in which one or more dam portions surrounding the display area are arranged, and a junction area surrounding the dam area. The sub-area includes a bending area that is transformed into a bent shape; a first sub-area disposed between one side of the bending area and the main area; and a second sub-area connected to the other side of the bending area. The circuit layer includes a power supply line that is configured to transmit power. The power supply line includes a main supply portion disposed in the non-display area; a sub-connection portion extending from the main supply portion to the sub-area; and a branch portion disposed in the junction area and protruding from one side of the sub-connection portion. The branch portion is spaced apart from a bank covering a bending hole of the bending area.

The branch portion is spaced apart from the at least one dam portion.

The bank includes a first extension portion extending to a portion of the junction area adjacent to the sub-area; and a first groove portion facing the branch portion, spaced apart from the branch portion, and concavely recessed in a direction spaced apart from the branch portion compared to the first extension portion. One dam portion adjacent to the junction area among the one or more dam portions includes a second extension portion extending to another portion of the junction area adjacent to the dam area; and a second groove portion facing the branch portion, spaced apart from the branch portion, and concavely recessed in a direction spaced apart from the branch portion compared to the second extension portion.

The display device further comprises a pressing layer disposed on the branch portion and covering the branch portion, an edge of the first groove portion, and an edge of the second groove portion.

The display device further comprises a touch sensor layer disposed on the sealing layer. The touch sensor layer includes a first touch conductive layer disposed on the sealing layer; a touch interlayer insulating layer covering the first touch conductive layer; a second touch conductive layer disposed on the touch interlayer insulating layer; and a touch planarization layer covering the second touch conductive layer. The pressing layer is disposed on the same layer as the first touch conductive layer.

The branch portion includes one or more branch main portions extending parallel to the sub-connection portion; and a branch sub-portion connecting the sub-connection portion and the one or more branch main portions. The branch sub-portion is disposed to be adjacent to the sub-area.

One edge of a portion of the sub-connection portion overlapping the junction area includes irregularities arranged along an extension direction of the sub-connection portion. An edge of the branch portion includes irregularities arranged along an extension direction of the branch portion. The irregularities are spaced apart from the bank and the at least one dam portion.

The power supply line further includes protrusions arranged along an edge of a portion of the sub-connection portion overlapping the junction area and an edge of the branch portion. An edge of each of the protrusions has an irregularity shape. The protrusions are spaced apart from the bank and the at least one dam portion.

The power supply line includes a first power supply line and a second power supply line are configured to respectively transmit first power and second power having different voltage levels.

According to an aspect of the present disclosure, there is provided a display device comprises a substrate; a circuit layer disposed on the substrate; an element layer disposed on the circuit layer; and a sealing layer disposed on the element layer. The substrate includes a main area and a sub-area protruding from one side of the main area. The main area includes a display area in which light emitting areas are disposed, and a non-display area disposed around the display area. The non-display area includes a dam area in which one or more dam portions surrounding the display area are arranged, and a junction area surrounding the dam area. The sub-area includes a bending area that is transformed into a bent shape; a first sub-area disposed between one side of the bending area and the main area; and a second sub-area connected to the other side of the bending area. The element layer includes light emitting elements disposed in the light emitting areas. The circuit layer includes light emitting pixel drivers electrically connected to the light emitting elements, and a power supply line that is configured to transmit power for driving the light emitting elements to the light emitting pixel drivers or the light emitting elements. The power supply line includes a main supply portion disposed in the non-display area; a sub-connection portion extending from the main supply portion to the sub-area; and a branch portion disposed in the junction area and protruding from one side of the sub-connection portion. One edge of a portion of the sub-connection portion overlapping the junction area includes irregularities arranged along an extension direction of the sub-connection portion. An edge of the branch portion includes irregularities arranged along an extension direction of the branch portion. The irregularities are spaced apart from a bank covering a bending hole of the bending area.

The irregularities are spaced apart from the at least one dam portion.

The branch portion includes one or more branch main portions extending parallel to the sub-connection portion; a branch sub-portion connecting the sub-connection portion and the one or more branch main portions. The branch sub-portion is disposed to be adjacent to the sub-area.

The bank includes a first extension portion extending to a portion of the junction area adjacent to the sub-area; and a first groove portion facing the branch portion, spaced apart from the branch portion, and concavely recessed in a direction spaced apart from the branch portion compared to the first extension portion. One dam portion adjacent to the junction area among the one or more dam portions includes a second extension portion extending to another portion of the junction area adjacent to the dam area; and a second groove portion facing the branch portion, spaced apart from the branch portion, and concavely recessed in a direction spaced apart from the branch portion compared to the second extension portion.

The display device further comprises a pressing layer disposed on the branch portion and covering the branch portion, an edge of the first groove portion, and an edge of the second groove portion.

The display device further comprises a touch sensor layer disposed on the sealing layer. The touch sensor layer includes a first touch conductive layer disposed on the sealing layer; a touch interlayer insulating layer covering the first touch conductive layer; a second touch conductive layer disposed on the touch interlayer insulating layer; and a touch planarization layer covering the second touch conductive layer. The pressing layer is disposed on the same layer as the first touch conductive layer.

According to an aspect of the present disclosure, there is provided a display device comprises a substrate; a circuit layer disposed on the substrate; an element layer disposed on the circuit layer; and a sealing layer disposed on the element layer. The substrate includes a main area and a sub-area protruding from one side of the main area. The main area includes a display area in which light emitting areas are disposed, and a non-display area disposed around the display area. The non-display area includes a dam area in which one or more dam portions surrounding the display area are arranged, and a junction area surrounding the dam area. The sub-area includes a bending area that is transformed into a bent shape; a first sub-area disposed between one side of the bending area and the main area; and a second sub-area connected to the other side of the bending area. The element layer includes light emitting elements disposed in the light emitting areas. The circuit layer includes light emitting pixel drivers electrically connected to the light emitting elements, and a power supply line that is configured to transmit power for driving the light emitting elements to the light emitting pixel drivers or the light emitting elements. The power supply line includes a main supply portion disposed in the non-display area; a sub-connection portion extending from the main supply portion to the sub-area; a branch portion disposed in the junction area and protruding from one side of the sub-connection portion; and protrusions arranged along an edge of a portion of the sub-connection portion overlapping the junction area and an edge of the branch portion. An edge of each of the protrusions has an irregularity shape. The protrusions are spaced apart from the bank and the at least one dam portion.

The irregularities are spaced apart from the at least one dam portion.

The branch portion includes one or more branch main portions extending parallel to the sub-connection portion; a branch sub-portion connecting the sub-connection portion and the one or more branch main portions. The branch sub-portion is disposed to be adjacent to the sub-area.

The bank includes a first extension portion extending to a portion of the junction area adjacent to the sub-area; and a first groove portion facing the branch portion, spaced apart from the branch portion, and concavely recessed in a direction spaced apart from the branch portion compared to the first extension portion. One dam portion adjacent to the junction area among the one or more dam portions includes a second extension portion extending to another portion of the junction area adjacent to the dam area; and a second groove portion facing the branch portion, spaced apart from the branch portion, and concavely recessed in a direction spaced apart from the branch portion compared to the second extension portion.

The display device further comprises a pressing layer disposed on the branch portion and covering the branch portion, an edge of the first groove portion, and an edge of the second groove portion.

The display device further comprises a touch sensor layer disposed on the sealing layer. The touch sensor layer includes a first touch conductive layer disposed on the sealing layer; a touch interlayer insulating layer covering the first touch conductive layer; a second touch conductive layer disposed on the touch interlayer insulating layer; and a touch planarization layer covering the second touch conductive layer. The pressing layer is disposed on the same layer as the first touch conductive layer.

The display device according to the embodiments includes the substrate, the circuit layer, the element layer, and the sealing layer. The substrate includes a main area and a sub-area protruding from one side of the main area. The main area includes the display area in which the light emitting areas are disposed, and the non-display area disposed around the display area. The non-display area includes a dam area in which one or more dam portions surrounding the display area are arranged, and a junction area surrounding the dam area. The sub-area includes a bending area that is transformed into a bent shape, a first sub-area disposed between one side of the bending area and the main area, and a second sub-area connected to the other side of the bending area.

The circuit layer includes a power supply line that is configured to transmit power. That is, the circuit layer includes light emitting pixel drivers electrically connected to light emitting elements of an element layer, and a power supply line that is configured to transmit power for driving the light emitting elements to the light emitting pixel drivers or the light emitting elements.

The power supply line includes a main supply portion disposed in the non-display area, a sub-connection portion extending from the main supply portion to the sub-area, and a branch portion disposed in the boding area and protruding from one side of the sub-connection portion.

According to embodiments, the branch portion is spaced apart from a bank covering a bending hole in the bending area.

According to embodiments, the branch portion may be spaced apart from one or more dam portions arranged in the dam area.

The bank includes a structure in which two or more bank layers each including an organic insulating material are stacked, and each of the one or more dam portions includes a structure in which two or more dam layers each including an organic insulating material are stacked.

In accordance with one or more embodiments, a display device includes a power supply line in a non-display area and including a sub-connection portion; at least one dam in a circuit layer and surrounding a display area adjacent to the non-display area; and a junction area between the at least one dam and a bending area, wherein the at least one dam limits a sealing layer from passing into the junction area, and wherein the power supply line includes one or more branch portions located in the junction area and protruding from one side of the sub-connection portion, the one or more branch portions increasing a circumference length of the sub-connection portion of the power supply line.

The display device may include a bank covering a bending hole in the bending area, wherein the one or more branch portions are spaced from the bank. The bank may include an organic insulating material. The one or more branch portions may be spaced from the bank by a distance that corresponds to an angle of a side surface of the bank.

The one or more branch portions may be spaced from the at least one dam. The one or more branch portions may be spaced from the at least one dam by a distance which corresponds to an angle of a side surface of the at least one dam.

The at least one dam may include an organic insulating material. The one or more branch portions may include one or more branch main portions extending parallel to the sub-connection portion, and a branch sub-portion connecting the one or more branch main portions to the sub-connection portion. The sub-connection portion may include irregularities. The one or more branch portions may include irregularities. The irregularities may include concave portions and convex portions.

The sub-connection portion may include at least one irregularity in a bank area. The one or more branch portions may include a plurality of protrusions. The sub-connection portion may include protrusions. The sealing layer may be in contact with an inorganic insulating material of the circuit layer at the junction area.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is a plan view illustrating the display device of FIG. 1 according to an embodiment;

FIG. 3 is a cross-sectional view taken along line A-A′ of FIG. 2 according to an embodiment;

FIG. 4 is a plan view illustrating a substrate of FIG. 3 according to embodiments;

FIG. 5 is a layout view illustrating portion B of FIG. 4 according to an embodiment;

FIG. 6 is an equivalent circuit diagram illustrating a light emitting pixel driver of FIG. 5 according to embodiments;

FIG. 7 is a plan view illustrating a touch sensor layer of FIG. 3 according to embodiments;

FIG. 8 is an enlarged view illustrating portion D of FIG. 7 according to an embodiment;

FIG. 9 is a cross-sectional view taken along line E-E′ of FIG. 8 according to an embodiment;

FIG. 10 is a layout view illustrating portion C of FIG. 4 according to embodiments;

FIG. 11 is a cross-sectional view taken along line F-F′ of FIG. 10 according to an embodiment;

FIG. 12 is a cross-sectional view taken along line G-G′ of FIG. 10 according to an embodiment;

FIG. 13 is a cross-sectional view taken along line H-H′ of FIG. 10 according to an embodiment;

FIG. 14 is a cross-sectional view taken along line H-H′ of FIG. 10 according to an embodiment;

FIG. 15 is a layout view illustrating portion I of FIG. 10 according to an embodiment;

FIG. 16 is a layout view illustrating portion I of FIG. 10 according to an embodiment;

FIG. 17 is a layout view illustrating portion I of FIG. 10 according to an embodiment;

FIG. 18 is an enlarged view illustrating portion J of FIG. 17 according to an embodiment;

FIG. 19 is a layout view illustrating portion I of FIG. 10 according to an embodiment;

FIG. 20 is an enlarged view illustrating portion K of FIG. 19 according to an embodiment;

FIG. 21 is a layout view illustrating portion C of FIG. 4 according to an embodiment;

FIG. 22 is a layout view illustrating portion L of FIG. 21 according to an embodiment; and

FIG. 23 is a cross-sectional view taken along line M-M′ of FIG. 21 according to an embodiment.

### DETAILED DESCRIPTION OF THE EMBODIMENTS

Embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

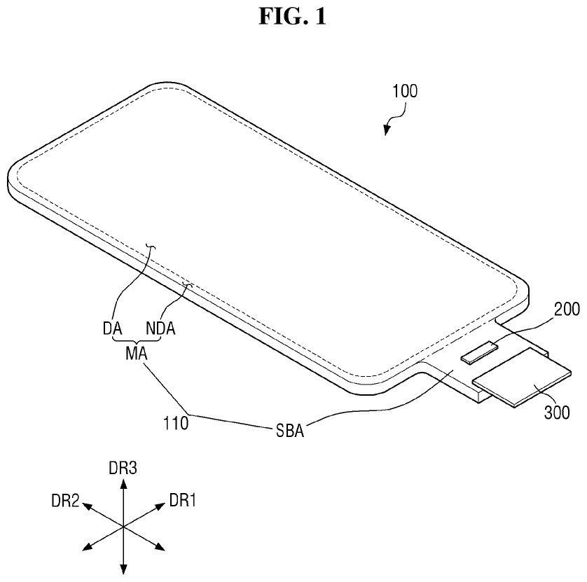

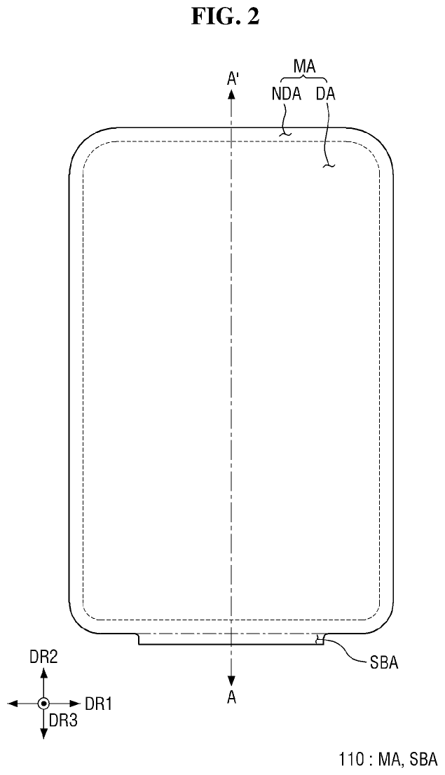

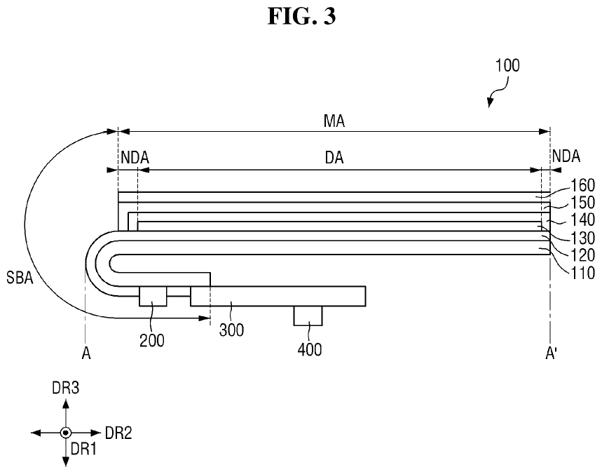

FIG. 1 is a perspective view illustrating a display device 100 according to an embodiment. FIG. 2 is a plan view illustrating the display device 100 of FIG. 1. FIG. 3 is a cross-sectional view taken along line A-A′ of FIG. 2.

Referring to FIGS. 1 and 2, the display device 100 displays a moving image or a still image, and may be used as a display screen for various products. Examples include televisions, laptop computers, monitors, billboards, and Internet of Things (IoT) devices, as well as portable electronic devices such as mobile phones, smartphones, tablet personal computers (PC), smartwatches, watch phones, mobile communication terminals, electronic organizers, electronic books, portable multimedia players (PMP), navigation devices, and ultra mobile PCs (UMPC).

The display device 100 may be a light emitting display device such as an organic light emitting display device using an organic light emitting diode, a quantum dot light emitting display device including a quantum dot light emitting layer, an inorganic light emitting display device including an inorganic semiconductor, or a micro light emitting display device using a micro or nano light emitting diode (micro or nano LED). Hereinafter, for illustrative purposes, the display device 100 is assumed to be an organic light emitting display device. However, the present disclosure is not limited thereto and may be applied to display devices including organic insulating materials, organic light emitting materials, and metal materials.

The display device 100 may be formed to be flat, but is not limited thereto. For example, the display device 100 may include curved surface portions formed at left and right distal ends thereof and having a constant curvature or a variable curvature. In addition, the display device 100 may be flexibly formed to be curved, bent, folded, or rolled.

As illustrated in FIGS. 1, 2, and 3, the display device 100 includes a substrate 110 which may include a main area MA corresponding to a display surface of the display device 100 and a sub-area SBA protruding from one side of the main area MA. As illustrated in FIG. 2, the main area MA may include a display area DA disposed at most of the center and a non-display area NDA disposed around the display area DA.

The display area DA may be formed in a rectangular plane having a short side in a first direction DR1 and a long side in a second direction DR2 intersecting the first direction DR1. A corner where the short side in the first direction DR1 and the long side in the second direction DR2 meet may be rounded to have a predetermined curvature or may be formed at a right angle. The planar shape of the display area DA is not limited to the quadrangular shape. In some embodiments, the display area DA may be formed to have other polygonal shapes, a circular shape, or an oval shape.

The non-display area NDA may be disposed at an edge (or bezel or periphery) of the main area MA to surround the display area DA.

The sub-area SBA may be an area protruding from the non-display area NDA of the main area MA to one side in the second direction DR2. Because a portion of the sub-area SBA is deformed into a curved shape, another portion of the sub-area SBA may be disposed on a rear surface of the display device 100. FIGS. 2 and 3 illustrate the display device 100 with a portion of the sub-area SBA that is curved.

Referring to FIG. 3, the display device 100 according to embodiments includes a substrate 110, a circuit layer 120 disposed on the substrate 110, and an element layer 130 disposed on the circuit layer 120. The display device 100 according to embodiments may further include a sealing layer 140 disposed on the element layer 130, and a touch sensor layer 150 disposed on the sealing layer 140. In addition, the display device 100 according to embodiments may further include a polarizing layer 160 disposed on the touch sensor layer 150 to reduce reflection of external light.

The substrate 110 may be made of an insulating material such as a polymer resin. For example, the substrate 110 may be made of polyimide. The substrate 110 may be a flexible substrate that may be bent, folded, or rolled. Alternatively, the substrate 110 may be made of an insulating material such as glass. The substrate 110 may include a main area MA and a sub-area SBA. The main area MA may include a display area DA and a non-display area NDA as previously indicated.

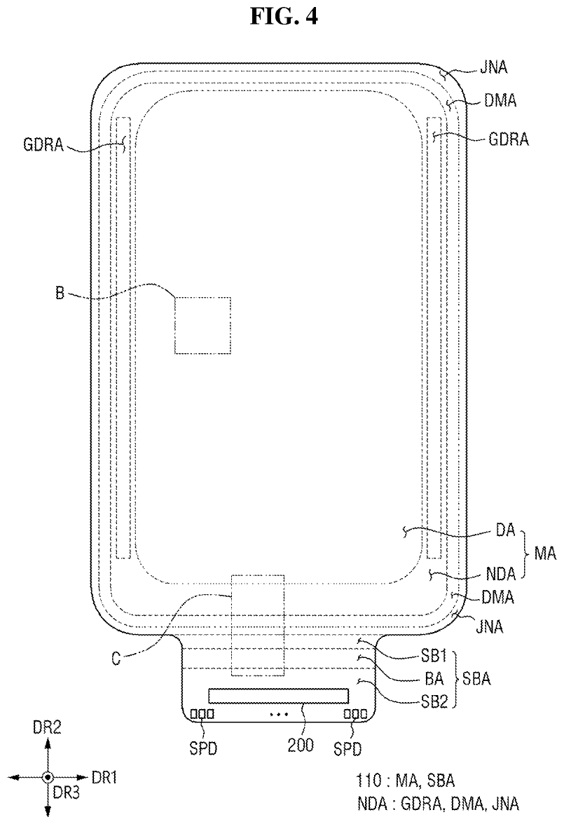

FIG. 4 is a plan view illustrating substrate 110 of FIG. 3 according to embodiments.

Referring to FIG. 4, the substrate 110 of the display device 100 according to embodiments may include a main area MA corresponding to a display surface and a sub-area SBA protruding from one side of the main area MA. The main area MA may include a display area DA disposed at most of the center and a non-display area NDA disposed at an edge and surrounding the display area DA.

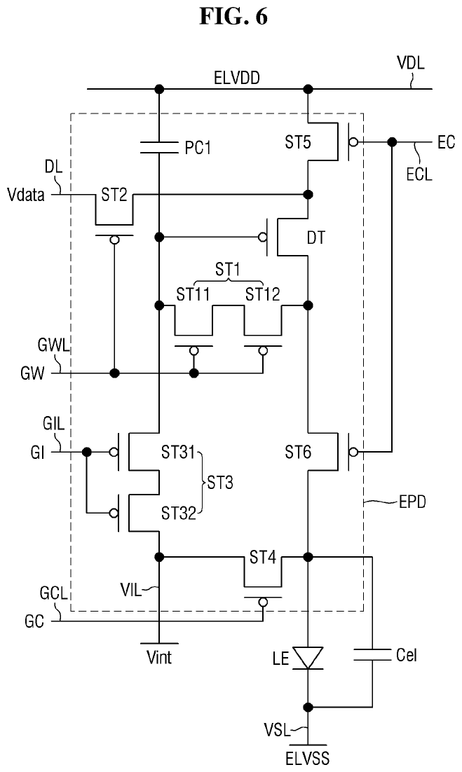

The non-display area NDA may include a gate driving circuit area GDRA where a gate driving circuit is disposed. The gate driving circuit area GDRA may be disposed in a portion of the non-display area NDA adjacent to at least one side of the display area DA in the first direction DR1. The gate driving circuit in the gate driving circuit area GDRA may sequentially transmit gate signals to gate lines. The gate lines may include, for example, a scan write line (GWL) that transmits a scan write signal (GW), a scan initialization line (GIL) that transmits a scan initialization signal (GI), a gate control line (GCL) that transmits a gate control signal (GC), and an emission control line ECL that transmits an emission control signal (EC). See, for example, FIG. 6 which shows these features a relative to a pixel.

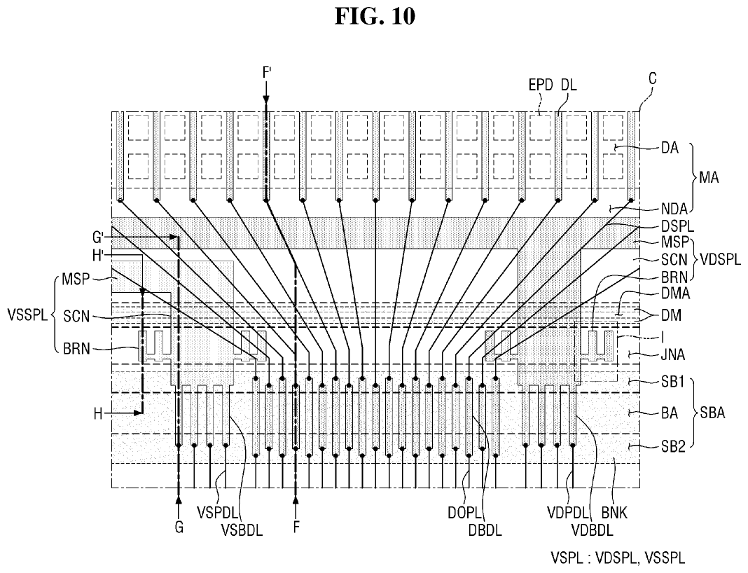

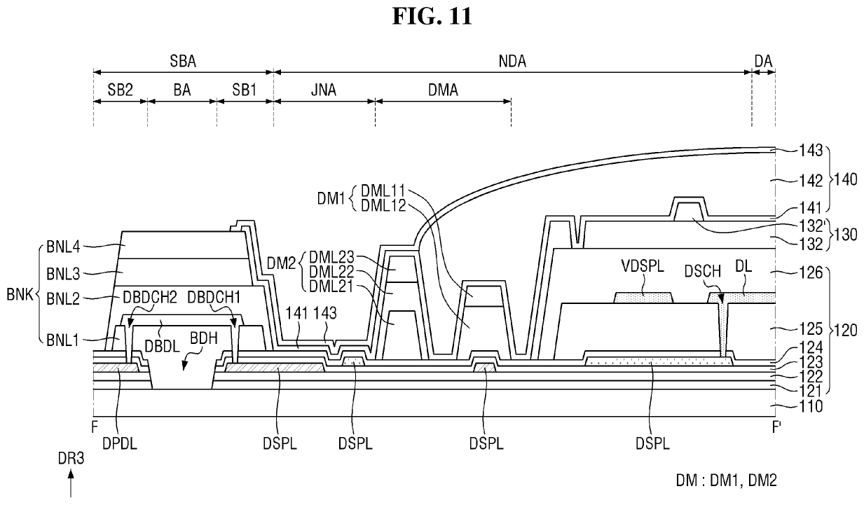

The non-display area NDA may include a dam area DMA surrounding the display area DA, and a junction area JNA surrounding the dam area DMA. One or more dam portions (e.g., DM in FIG. 10) surrounding the display area DA may be arranged in the dam area DMA. Each of the one or more dam portions DM may include a structure in which two or more dam layers are stacked. Each of the two or more dam layers may include an organic insulating material. Because each of the dam layers of the organic insulating material is disposed with a relatively large thickness, valleys may be generated on both sides of each of the one or more dam portions DM. Accordingly, due to the valleys generated by the one or more dam portions DM, an area where an organic layer (142 in FIG. 11) of the sealing layer 140 spreads may be limited.

A junction structure between inorganic layers (141 and 142 in FIG. 11) of the sealing layer 140 and an inorganic layer (124 in FIG. 11) of the circuit layer 120 may be disposed in the junction area JNA.

The sub-area SBA may include a bending area BA that is transformed into a bent shape, a first sub-area SB1 disposed between one side of the bending area BA and the main area MA, and a second sub-area SB2 connected to the other side of the bending area BA. When the bending area BA is transformed into the bent shape, the second sub-area SB2 is disposed below the substrate 110 and may overlap the main area MA.

A display driving circuit 200 may be disposed in the second sub-area SB2.

Signal pads SPD bonded to a circuit board 300 may be disposed at one edge of the second sub-area SB2.

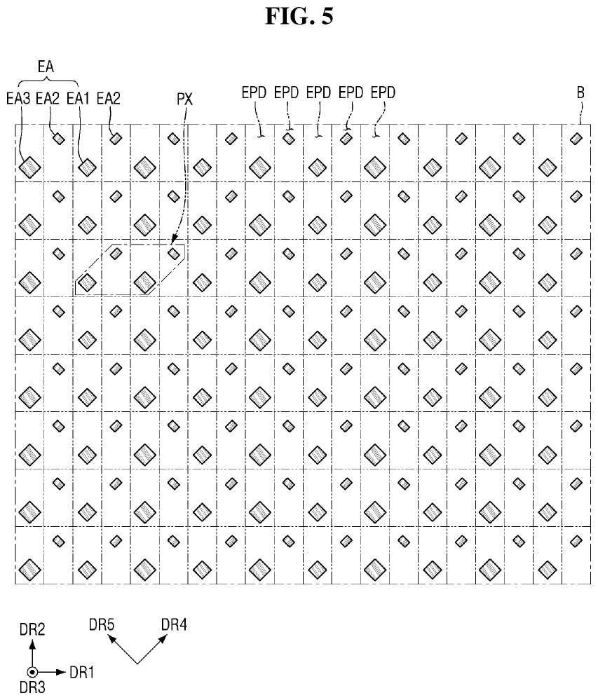

FIG. 5 is a layout view illustrating portion B of FIG. 4 according to an embodiment.

Referring to FIG. 5, the display area DA of the display device 100 according to embodiments may include light emitting areas EA. In addition, the display area DA may include a non-light emitting area disposed in a spaced portions between the light emitting areas EA.

The element layer 130 may include light emitting elements (LE in FIG. 6) disposed in each of the light emitting areas EA.

The circuit layer 120 may include light emitting pixel drivers EPD that are electrically connected to the light emitting elements of the element layer 130, respectively. The light emitting pixel drivers EPD may be arranged parallel to each other in the first direction DR1 and the second direction DR2 in the display area DA.

The light emitting areas EA may have a predetermined shape, e.g., a rhombic planar shape or a rectangular planar shape. However, this is only an example, and the planar shape of the light emitting areas EA according to an embodiment is not limited to that illustrated in FIG. 5. For example, the light emitting areas EA may have a polygonal planar shape such as a square, pentagon, or hexagon, or a circular or oval planar shape including curved edges.

Each of the light emitting areas EA may include a first light emitting area EA1 that emits light of a first color in a predetermined wavelength band, second light emitting areas EA2 that emit light of a second color in a wavelength band lower than that of the first color, and a third light emitting area EA3 that emits light of a third color in a wavelength band lower than that of the second color. As an example, the first color may be red in a wavelength band of approximately 600 nm to 750 nm. The second color may be green in a wavelength band of approximately 480 nm to 560 nm. The third color may be blue in a wavelength band of approximately 370 nm to 460 nm.

The first light emitting areas EA1 and the third light emitting areas EA3 may be alternately disposed in at least one of the first direction DR1 or the second direction DR2.

The second light emitting areas EA2 may be arranged parallel to each other in at least one of the first direction DR1 or the second direction DR2. In addition, the second light emitting areas EA2 may be adjacent to the first light emitting areas EA1 and the third light emitting areas EA3 in diagonal directions DR4 and DR5 intersecting the first and second directions DR1 and DR2. The arrangement of the light emitting areas EA1, EA2, and EA3 may be different in other embodiments.

Pixels PX that display each luminance and color may be provided by the first light emitting area EA1, the second light emitting area EA2, and the third light emitting area EA3 adjacent to each other among the light emitting areas EA. For example, the pixels PX may be basic units that emit light of various colors, including white, at predetermined luminance. Each of the pixels PX may include at least one first light emitting area EA1, at least one second light emitting area EA2, and at least one third light emitting area EA3 adjacent to each other. Accordingly, each of the pixels PX may display various colors through mixing of light emitted from the first, second, and third light emitting areas EA1, EA2, and EA3 adjacent to each other.

FIG. 6 is an equivalent circuit diagram illustrating a light emitting pixel driver EPD (or pixel circuit) of FIG. 5.

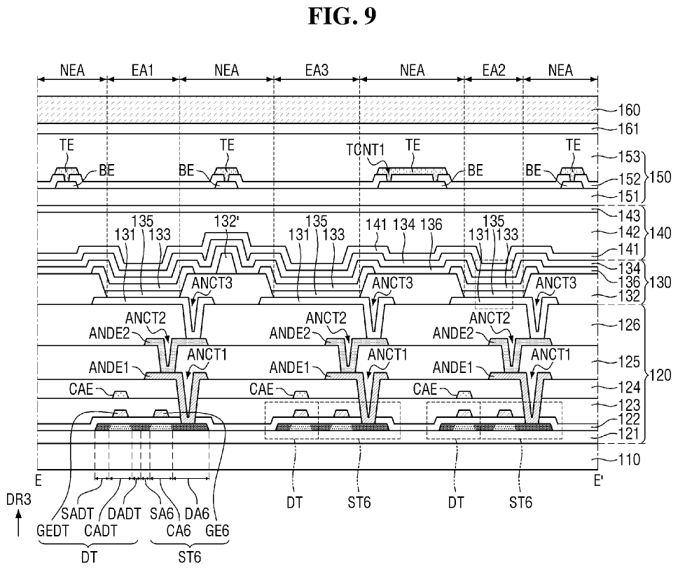

Referring to FIG. 6, one of the light emitting elements LE of the element layer 130 may be electrically connected between one of the light emitting pixel drivers EPD of the circuit layer 120 and a second power ELVSS. For example, an anode electrode (131 in FIG. 9) of the light emitting element LE may be electrically connected to the light emitting pixel driver EPD. The second power ELVSS having a lower voltage level than a first power ELVDD may be applied to a cathode electrode (134 in FIG. 9) of the light emitting element LE. A capacitor Cel connected in parallel with the light emitting element LE represents parasitic capacitance between the anode electrode 131 and the cathode electrode 134.

The circuit layer 120 may further include a first power line VDL and an initialization power line VIL. The first power line VDL transmits the first power ELVDD. The initialization power line VIL transmits the initialization power Vint. The circuit layer 120 may further include a scan write line GWL that transmits a scan write signal GW, a scan initialization line GIL that transmits a scan initialization signal GI, an emission control line ECL that transmits an emission control signal EC, and a gate control line GCL that transmits a gate control signal GC.

As further shown in FIG. 6, the light emitting pixel driver EPD of one of the circuit layers 120 may include a driving transistor DT that generates a driving current for driving the light emitting element LE, two or more transistors ST1 to ST6 electrically connected to the driving transistor DT, and at least one capacitor PC1.

The driving transistor DT is connected in series with the light emitting element LE between the first power ELVDD and the second power ELVSS. For example, a first electrode (e.g., a source electrode) of the driving transistor DT may be electrically connected to the first power line VDL through a fifth transistor ST5. A second electrode (e.g., a drain electrode) of the driving transistor DT may be electrically connected to the anode electrode 131 of the light emitting element LE through a sixth transistor ST6. The first electrode of the driving transistor DT may be electrically connected to the data line DL through a second transistor ST2.

A gate electrode of the driving transistor DT may be electrically connected to the first power line VDL through a first capacitor PC1. For example, the first capacitor PC1 may be electrically connected between the gate electrode of the driving transistor DT and the first power line VDL. Accordingly, a potential of the gate electrode of the driving transistor DT may be maintained at the first power ELVDD by the first power line VDL.

In addition, when the data signal Vdata of the data line DL is transmitted to the first electrode of the driving transistor DT through the turned-on second transistor ST2, a voltage difference corresponding to the first power ELVDD and the data signal Vdata may be generated between the gate electrode of the driving transistor DT and the first electrode of the driving transistor DT. In this case, when the voltage difference between the gate electrode of the driving transistor DT and the first electrode of the driving transistor DT (e.g., a gate-source voltage difference) is a threshold voltage or more, the driving transistor DT may be turned on, thereby generating a drain-source current of the driving transistor DT corresponding to the data signal Vdata. As described below, this drain-source current causes the light emitting element LE to emit light with a luminance that corresponds to the data signal Vdata.

Subsequently, when the fifth transistor ST5 and the sixth transistor ST6 are turned on, the driving transistor DT may be connected in series with the light emitting element LE between the first power line VDL and a second power line VSL. Accordingly, the drain-source current of the driving transistor DT corresponding to the data signal Vdata may be supplied as a driving current of the light emitting element LE. Accordingly, the light emitting element LE may emit light with luminance corresponding to the data signal Vdata.

A first transistor ST1 may be electrically connected between the gate electrode of the driving transistor DT and the second electrode of the driving transistor DT. The first transistor ST1 may be turned on by the scan write signal GW of the scan write line GWL.

In one embodiment, the first transistor ST1 may include a plurality of sub-transistors connected in series. As an example, the first transistor ST1 may include a first sub-transistor ST11 and a second sub-transistor ST12. A first electrode of the first sub-transistor ST11 may be connected to the gate electrode of the driving transistor DT, a second electrode of the first sub-transistor ST11 may be connected to a first electrode of the second sub-transistor ST12, and a second electrode of the second sub-transistor ST12 may be connected to the second electrode of the driving transistor DT. In this way, a potential of the gate electrode of the driving transistor DT may be prevented from being changed due to leakage current caused by the first transistor ST1 that is not turned on.

The second transistor ST2 may be electrically connected between the first electrode of the driving transistor DT and the data line DL. The second transistor ST2 may be turned on by the scan write signal GW of the scan write line GWL.

A third transistor ST3 may be connected between the gate electrode of the driving transistor DT and the initialization power line VIL. The third transistor ST3 may be turned on by the scan initialization signal GI of the scan initialization line GIL.

The third transistor ST3 may include a plurality of sub-transistors connected in series. As an example, the third transistor ST3 may include a third sub-transistor ST31 and a fourth sub-transistor ST32. A first electrode of the third sub-transistor ST31 may be connected to the gate electrode of the driving transistor DT, a second electrode of the third sub-transistor ST31 may be connected to a first electrode of the fourth sub-transistor ST32, and a second electrode of the fourth sub-transistor ST32 may be connected to the initialization power line VIL. In this way, the potential of the gate electrode of the driving transistor DT may be prevented from being changed due to leakage current caused by the third transistor ST3 that is not turned on.

A fourth transistor ST4 may be electrically connected between the anode electrode 131 of the light emitting element LE and the initialization power line VIL. The fourth transistor ST4 may be turned on by the gate control signal GC of the gate control line GCL to initialize the light emitting element LE.

The fifth transistor ST5 may be electrically connected between the first electrode of the driving transistor DT and the first power line VDL.

The sixth transistor ST6 may be electrically connected between the second electrode of the driving transistor DT and the anode electrode 131 of the light emitting element LE. The fifth transistor ST5 and the sixth transistor ST6 may be turned on by the emission control signal EC of the emission control line ECL to allow for emission of light from the light emitting element LE.

As illustrated in FIG. 6, the driving transistor DT and the first to sixth transistors ST1 to ST6 may be provided as P-type MOSFETs. However, this is only an example, and some of the driving transistor DT and the first to sixth transistors ST1 to ST6 may also be provided as N-type MOSFETs. As an example, the first transistor ST1 and the third transistor ST3 may be provided as N-type MOSFETs.

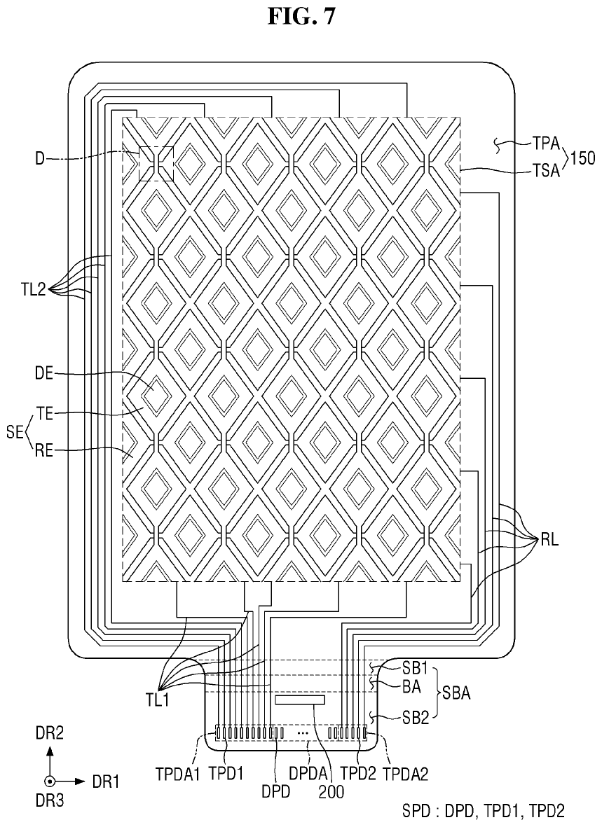

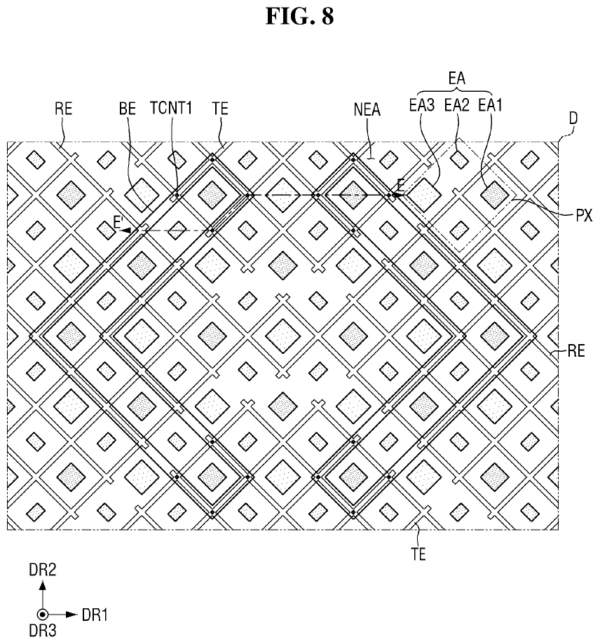

FIG. 7 is a plan view illustrating a touch sensor layer of FIG. 3 according to embodiments. FIG. 8 is an enlarged view illustrating portion D of FIG. 7 according to an embodiment.

FIG. 7 illustrates a capacitive touch sensor layer 150. In this case, a touch driving circuit 400 may detect a touch based on whether there is a change in capacitance. However, the illustration in FIG. 7 is merely an example for convenience of explanation, and the touch sensor layer 150 according to an embodiment is not limited to the illustration in FIG. 7. FIG. 7 illustrates only some of the components of the touch sensor layer 150 for convenience of explanation.

Referring to FIG. 7, the touch sensor layer 150 may be disposed in the main area MA. The touch sensor layer 150 may include a touch sensing area TSA for detecting a touch of a user's finger or stylus, and a touch peripheral area TPA around the touch sensing area TSA.

The touch sensing area TSA may be wider than the display area DA and may be similar to the display area DA. Accordingly, the touch peripheral area TPA around the touch sensing area TSA may be similar to the non-display area NDA around the display area DA. As an example, the touch sensing area TSA may overlap the display area DA and the edge of the non-display area NDA adjacent to the display area DA. In this case, the touch peripheral area TPA may overlap the remaining portion of the non-display area NDA that does not correspond to the touch sensing area TSA.

The touch sensor layer 150 may include sensor electrodes SE and dummy electrodes DE arranged in a predetermined pattern (e.g., a matrix) in the touch sensing area TSA and generating mutual capacitance. Sensor lines TL1, TL2, and RL may be disposed in the touch peripheral area TPA.

The sensor electrode SE may include a touch driving electrode TE to which a driving signal is applied, and a receiving electrode RE for detecting a voltage charged in the mutual capacitance with the touch driving electrode TE.

The sensor lines may include a first touch driving line TL1, a second touch driving line TL2, and a receiving line RL. Each of the first touch driving line TL1 and the second touch driving line TL2 may be electrically connected to two or more touch driving electrodes TE connected in the second direction DR2 among the touch driving electrodes TE.

The first touch driving line TL1 may extend from a portion of the touch peripheral area TPA between one side of the touch sensing area TSA in the second direction DR2 and the sub-area SBA to the sub-area SBA.

The second touch driving line TL2 may extend from a portion of the touch peripheral area TPA (that is in contact with the other side of the touch sensing area TSA in the second direction DR2) to the sub-area SBA through a part in contact with one side of the touch sensing area TSA in the first direction DR1.

The receiving line RL may be electrically connected to two or more receiving electrodes RE connected in the first direction DR1 among the receiving electrodes RE.

The receiving electrodes RE may be arranged in parallel in the first direction DR1. The receiving electrodes RE adjacent in the first direction DR1 may be electrically connected to each other through protruding portions in the first direction DR1.

The touch driving electrodes TE may be arranged in parallel in the second direction DR2. The touch driving electrodes TE adjacent in the second direction DR2 may be electrically connected to each other through a bridge electrode (e.g., BE in FIG. 8) in the second direction DR2.

Each of the touch driving electrodes TE and the receiving electrodes RE may have a predetermined shape surrounding a dummy electrode DE disposed, for example, at the center of each of the touch driving electrodes TE and receiving electrodes RE. The dummy electrode DE may be spaced apart from the touch driving electrode TE and the receiving electrode RE surrounding each dummy electrode DE. The dummy electrode DE may be maintained in a floating state.

FIG. 7 illustrates that each of the touch driving electrode TE, the receiving electrode RE, and the dummy electrode DE have a rhombic planar shape, but the embodiment is not limited to the illustration in FIG. 7. These electrodes may have a different shape in another embodiment. Moreover, the shapes of the electrodes may be different in an embodiment. As an example, the touch driving electrode TE, the receiving electrode RE, and the dummy electrode DE may have a planar shape such as a quadrangle shape other than a rhombus, a polygon other than a quadrangle, a circle, or an oval.

The display device 100 according to an embodiment may include signal pads SPD disposed in the second sub-area SB2 of the substrate 110 and to which the circuit board 300 is connected. The signal pads SPD may include display signal pads DPD and touch signal pads TPD1 and TPD2. The display signal pads DPD transmit and receive signals for driving the circuit layer 120. The touch signal pads TPD1 and TPD2 transmit and receive signals for driving the touch sensor layer 150.

As an example, the second sub-area SB2 may include a display pad area DPDA adjacent to the display driving circuit 200, and a first touch pad area TPDA1 and a second touch pad area TPDA2 disposed on respective sides of the display pad area DPDA. Display pads DPD, for transmitting and receiving signals transmitted to the circuit layer 120 or the display driving circuit 200, may be disposed in the display pad area DPDA. First touch pads TPD1, which are electrically connected to the first touch driving line TL1 and the second touch driving line TL2, respectively, may be disposed in the first touch pad area TPDA1. Each of the second touch pads TPD2 may be electrically connected to the receiving line RL and may be disposed in the second touch pad area TPDA2.

Referring to FIG. 8, the bridge electrode BE may be disposed on a first touch conductive layer on a touch buffer layer (e.g., see 151 in FIG. 9), and the touch driving electrode TE and the receiving electrode RE may be disposed on a second touch conductive layer on a touch interlayer insulating layer (e.g., see 152 in FIG. 9). The touch driving electrode TE and the receiving electrode RE may be spaced apart from each other. In FIG. 8, the bridge electrode BE has a shape that includes at least one bent section, but the shape of the bridge electrode BE according to an embodiment is not limited to that illustrated in FIG. 8.

The touch driving electrodes TE adjacent to the second direction DR2 may be electrically connected to each other through two or more bridge electrodes BE. In this way, reliability of an electrical connection between the touch driving electrodes TE may be improved. FIG. 8 shows that two bridge electrodes BE parallel to each other are disposed between the touch driving electrodes TE adjacent in the second direction DR2, but the embodiment is not limited to that illustrated in FIG. 8. The bridge electrode BE may be electrically connected to the touch driving electrodes TE through touch electrode connection holes TCNT1.

Each of the touch driving electrode TE, the receiving electrode RE, and the bridge electrode BE may have, for example, a planar shape of a mesh or net structure. The dummy electrode DE may also have, for example, a planar shape of a mesh or net structure. Because the width overlapping the touch driving electrode TE, the receiving electrode RE, the dummy electrode DE, and the bridge electrode BE among the light emitting areas EA may be reduced, a decrease in light emission efficiency of the light emitting areas EA (due to the touch driving electrode TE, the receiving electrode RE, the dummy electrode DE, and the bridge electrode BE) may be reduced or prevented.

FIG. 9 is a cross-sectional view taken along line E-E′ of FIG. 8 according to an embodiment.

Referring to FIG. 9, the display device 100 according to embodiments may include the substrate 110, the circuit layer 120 on the substrate 110, the element layer 130 on the circuit layer 120, and the sealing layer 140 on the element layer 130. In addition, the display device 100 according to embodiments may include the touch sensor layer 150 on the sealing layer 140, and the polarizing layer 160 disposed on the touch sensor layer 150.

The substrate 110 may be made of an insulating material such as a polymer resin. For example, the substrate 110 may include polyimide.

The circuit layer 120 may include light emitting pixel drivers EPD, each of which may be electrically connected to the light emitting elements LE disposed in the light emitting areas EA.

The light emitting pixel drivers EPD may include a driving transistor DT and two or more transistors ST1 to ST6 electrically connected to the driving transistor DT. According to embodiments, each of the driving transistor DT and two or more transistors ST1 to ST6 may include a channel area CA, a source area SA, and a drain area DA made of a semiconductor layer, and a gate electrode GE made of a first gate conductive layer on a first gate insulating layer 122 covering the semiconductor layer.

The source area SA and drain area DA may be connected to respective sides of the channel area CA, respectively. The source area SA and drain area DA may have higher conductivity than the channel area CA. The gate electrode GE overlaps the channel area CA.

The first capacitor PC1 of the light emitting pixel drivers EPD may be provided in an overlapping area between a gate electrode GEDT of the driving transistor DT and a capacitor electrode CAE. The capacitor electrode CAE may be made of a second gate conductive layer on a second gate insulating layer 123 covering the first gate conductive layer.

The anode electrode 131 of the element layer 130 may be electrically connected to a drain area DA6 of the sixth transistor ST6 through a first anode connection electrode ANDE1 and a second anode connection electrode ANDE2.

The first anode connection electrode ANDE1 may be disposed on a first source/drain conductive layer on an interlayer insulating layer 124 covering the second gate conductive layer. The first anode connection electrode ANDE1 may be electrically connected to the drain area DA6 of the sixth transistor ST6 through a first anode contact hole ANCT1 penetrating through the interlayer insulating layer 124, the second gate insulating layer 123, and the first gate insulating layer 122.

The second anode connection electrode ANDE2 may be disposed on a second source/drain conductive layer on the first planarization layer 125 that covers the first source/drain conductive layer. The second anode connection electrode ANDE2 may be electrically connected to the first anode connection electrode ANDE1 through a second anode contact hole ANCT2 penetrating through the first planarization layer 125.

The anode electrode 131 of the element layer 130 may be disposed on a second planarization layer 126. The anode electrode 131 may be electrically connected to the second anode connection electrode ANDE2 through a third anode contact hole ANCT3, which penetrates through the second planarization layer 126.

For example, the circuit layer 120 may include a buffer layer 121 disposed on the substrate 110, semiconductor layers CADT, SADT, DADT, CA6, SA6, and DA6 disposed on the buffer layer 121, a first gate insulating layer 122 covering the semiconductor layer, first gate conductive layers GEDT and GE6 disposed on the first gate insulating layer 122, a second gate insulating layer 123 covering the first gate conductive layer, a second gate conductive layer CAE disposed on the second gate insulating layer 123, an interlayer insulating layer 124 covering the second gate conductive layer, a first source/drain conductive layer ADNE1 disposed on the interlayer insulating layer 124, a first planarization layer 125 covering the first source/drain conductive layer, a second source/drain conductive layer ANDE2 disposed on the first planarization layer 125, and a second planarization layer 126 covering the second source/drain conductive layer.

Each of the buffer layer 121, the first gate insulating layer 122, the second gate insulating layer 123, and the interlayer insulating layer 124 may be made of at least one inorganic film. As an example, each of the buffer layer 121, the first gate insulating layer 122, the second gate insulating layer 123, and the interlayer insulating layer 124 may be made of multiple films in which one or more inorganic films of silicon nitride, silicon oxynitride, silicon oxide, titanium oxide, and aluminum oxide are alternately stacked.

Each of the first planarization layer 125 and the second planarization layer 126 may be made of an organic film such as acryl resin, epoxy resin, phenolic resin, polyamide resin, or polyimide resin.

The semiconductor layers CADT, SADT, DADT, CA6, SA6, and DA6 may be made of one semiconductor material of poly silicon, amorphous silicon, and an oxide semiconductor.

The channel area CA of the semiconductor layer overlapping the gate electrode GE may maintain semiconductor characteristics, and the remaining source area SA and drain area DA thereof may be electrically conductive.

Each of the first gate conductive layer, the second gate conductive layer, the first source/drain conductive layer, and the second source/drain conductive layer may be formed of multiple layers of two or more of molybdenum (Mo), aluminum (Al), chromium (Cr), gold (Au), titanium (Ti), nickel (Ni), neodymium (Nd), or copper (Cu). Each of the first source/drain conductive layer and the second source/drain conductive layer may include a multilayer structure in which two or more metal layers are stacked.

The element layer 130 is disposed on the second planarization layer 126 of the circuit layer 120 and may include light emitting elements LE respectively disposed in the light emitting areas EA. The element layer 130 may include anode electrodes 131 respectively disposed in the light emitting areas EA, a pixel defining layer 132 disposed in the non-light emitting area NEA (which is a spaced area between the light emitting areas EA and covering an edge of each of the anode electrodes 131), a spacer layer 132′ disposed on a portion of the pixel defining layer 132, light emitting layers 133 disposed on each of the anode electrodes 131, and a cathode electrode 134 disposed on the pixel defining layer 132, the spacer layer 132′, and the light emitting layer 133.

The element layer 130 may further include first common layers 135 respectively disposed between the anode electrodes 131 and the light emitting layer 133, and a second common layer 136 disposed between the light emitting layers 133 and the cathode electrode 134. For example, each of the light emitting elements LE may include the anode electrode 131 and the cathode electrode 134 that face each other, and the light emitting layer 133 disposed therebetween. In one embodiment, each of the light emitting elements LE may further include the first common layer 135 disposed between the anode electrode 131 and the light emitting layer 133, and the second common layer 136 disposed between the light emitting layer 133 and the cathode electrode 134.

The first common layer 135 may include a hole transporting layer. In one embodiment, the first common layer 135 may further include a hole injection layer between the anode electrode 131 and the hole transporting layer.

The light emitting layer 133 on the first common layer 135 may be disposed in each of the light emitting areas EA. The light emitting layer 133 of the first light emitting area EA1, the light emitting layer 133 of the second light emitting area EA2, and the light emitting layer 133 of the third light emitting area EA3 may include different materials or organic light emitting materials. As an example, the light emitting layer 133 may be made of an organic light emitting material that converts electron-hole pairs into light. The organic light emitting material may include a host material and a dopant. The dopant may include, for example a phosphorescent material or a fluorescent material.

The second common layer 136 below the cathode electrode 134 may be entirely disposed in the display area DA including the light emitting areas EA. The second common layer 136 may include an electron transporting layer. In one embodiment, the second common layer 136 may further include an electron injection layer between the cathode electrode 134 and the electron transporting layer.

The sealing layer 140 may be disposed on the circuit layer 120 and cover the element layer 130. The sealing layer 140 may include a first sealing layer 141, a second sealing layer 142, and a third sealing layer 143. The first sealing layer 141 is disposed on the element layer 130 and is made of an inorganic insulating material. The second sealing layer 142 is disposed on the first sealing layer 141, overlaps the element layer 130, and includes an organic insulating material. The third sealing layer 143 is disposed on the first sealing layer 141, covers the second sealing layer 142, and includes an inorganic insulating material.

In one embodiment, the second sealing layer 142 may include an organic insulating material. Examples include an acryl resin, an epoxy resin, a phenolic resin, a polyamide resin, and a polyimide resin. The second sealing layer 142 may be prepared, for example, through a process of dropping an organic material in a liquid state onto the first sealing layer 141, spreading the organic material to cover the display area DA, and then curing the organic material.

Accordingly, according to embodiments, the display device 100 may include one or more dam portions (e.g., DM in FIGS. 10 to 14) that form at least one valley for limiting the range in which the organic material of the second sealing layer 142 spreads. As discussed in greater detail below, one or more dam portions DM may be disposed in the dam area DMA of the non-display area NDA. As explained, for example, relative to FIGS. 11 to 14, the one or more dam portions DM may limit the second sealing layer 142 from moving into the junction area JNA during formation of the layers of the display device. Since the second sealing layer is made of an organic insulating material, the one or more dam portions may prevent an organic insulating material from being included in the junction area.

More specifically, the second sealing layer 142 is spread within the dam area DMA in which one or more dam portions DM is disposed. Accordingly, the third sealing layer 143 may be bonded to the first sealing layer 141 in the junction area JNA disposed around the dam area DMA in the non-display area NDA. Each of the first sealing layer 141 and the third sealing layer 143 may include a structure in which one or more inorganic films of a silicon nitride layer, a silicon oxynitride layer, a silicon oxide layer, a titanium oxide layer, and an aluminum oxide layer are stacked. By making the first and third sealing layers 141 and 143 from inorganic material, the propagation of moisture in the junction area JNA may be limited.

According to embodiments, the touch sensor layer 150 may be disposed on the sealing layer 140, and the polarizing layer 160 may be disposed on the touch sensor layer 150. According to embodiments, the touch sensor layer 150 may include a first touch conductive layer BE disposed on the sealing layer 140, a touch interlayer insulating layer 152 covering the first touch conductive layer, second touch conductive layers TE and RE disposed on the touch interlayer insulating layer 152, and a touch planarization layer 153 covering the second touch conductive layers. The touch sensor layer 150 may further include a touch buffer layer 151 covering the sealing layer 140. In this case, the first touch conductive layer BE may be disposed on the touch buffer layer 151.

The bridge electrode BE may be disposed on the first touch conductive layer on the touch buffer layer 151.

The touch driving electrode TE and the receiving electrode RE may be disposed on the second touch conductive layer on the touch interlayer insulating layer 152.

The dummy electrode DE disposed inside each of the touch driving electrode TE and the receiving electrode RE, the first touch driving line TL1 and the second touch driving line TL2 connected to the touch driving electrode TE, and the receiving line RL connected to the receiving electrode RE may be disposed on the second touch conductive layer on the touch interlayer insulating layer 152, like the touch driving electrode TE and the receiving electrode RE.

The touch driving electrode TE may be electrically connected to the bridge electrode BE through the touch electrode connection hole TCNT1 penetrating through the touch interlayer insulating layer 152.

The polarizing layer 160 may be disposed on the touch planarization layer 153. In one embodiment, the polarizing layer 160 may also be disposed on a polarizing buffer layer 161 covering the touch planarization layer 153.

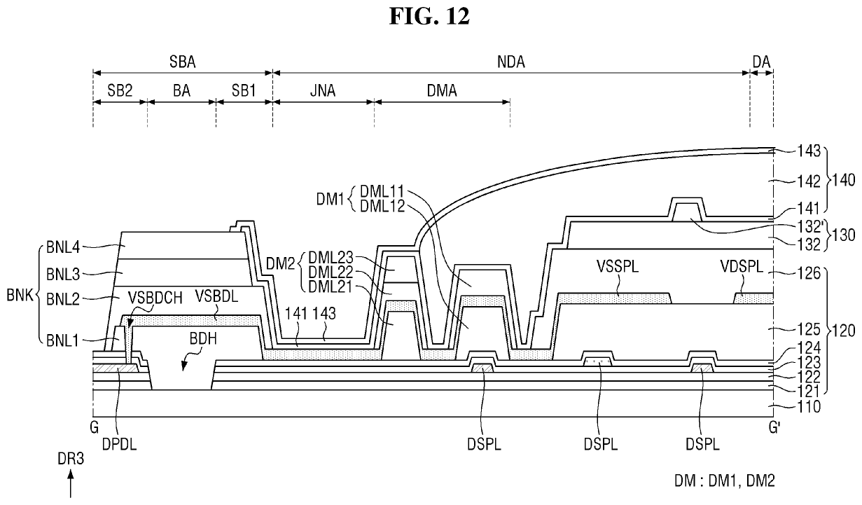

FIG. 10 is a layout view illustrating portion C of FIG. 4 according to embodiments. FIG. 11 is a cross-sectional view taken along line F-F′ of FIG. 10 according to an embodiment. FIG. 12 is a cross-sectional view taken along line G-G′ of FIG. 10 according to an embodiment.

Referring to FIG. 10, the circuit layer 120 of the display device 100 according to embodiments may include light emitting pixel drivers EPD electrically connected to the light emitting elements LE of the element layer 130, and a power supply line VSPL that transmits power for driving the light emitting elements LE to the light emitting pixel drivers EPD or light emitting elements LE.

The power supply line VSPL may include a first power supply line VDSPL and a second power supply line VSSPL that respectively transmit a first power ELVDD and a second power ELVSS having different voltage levels. Hereinafter, for brief description, the first power supply line VDSPL and the second power supply line VSSPL may be collectively referred to as the power supply line VSPL.

Each of the first power supply line VDSPL and the second power supply line VSSPL of the power supply line VSPL may include a main supply portion MSP disposed in the non-display area NDA, a sub-connection portion SCN extending from the main supply portion MSP to the sub-area SBA, and a branch portion BRN disposed in the junction area JNA and protruding from one side of the sub-connection portion SCN.

According to embodiments, the circuit layer 120 of the display device 100 may further include data lines DL that are electrically connected to the light emitting pixel drivers EPD, extend in the second direction DR2, and transmit data signals.

The circuit layer 120 may further include data supply lines DSPL, data bending lines DBDL, and data output lines DOPL. The data supply lines DSPL are disposed in the non-display area NDA, extend to the sub-area SBA, and are electrically connected to the data lines DL, respectively. The data bending lines DBDL are disposed in the bending area BA and are respectively connected to the data supply lines DSPL. The data output lines DOPL are disposed in the second sub-area SB2 and are electrically connected to the data bending lines DBDL, respectively. For example, the data lines DL may be electrically connected to the display driving circuit 200 of the second sub-area SB2 through the data supply lines DSPL, the data bending lines DBDL, and the data output lines DOPL.

Referring to FIG. 11, the circuit layer 120 of the display device 100 according to embodiments may include one or more dam portions DM sequentially arranged in the dam area DMA and an inorganic junction structure disposed in the junction area JNA. In accordance with one or more embodiments, since valleys where the interlayer insulating layer 124 is exposed are provided on respective sides of one or more dam portions DM, the area in which the second sealing layer 142 is disposed may be limited by disposing one or more dam portions DM. Since the second sealing layer 142 is made from an organic insulating material, this may prevent an organic sealing material from propagating into the junction area, thereby preventing moisture and oxygen from entering this region of the display device.

As an example, one or more dam portions DM may include a first dam portion DM1 surrounding the display area DA, and a second dam portion DM2 surrounding the first dam portion DM1. The first dam portion DM1 and the second dam portion DM2 may include two or more dam layers DML11 and DML12, and DML21, DML22, and DML23, respectively.

The first dam layer DML11 of the first dam portion DM1 may be disposed on the same layer as the first planarization layer 125. The second dam layer DML12 of the first dam portion DM1 may be disposed on the same layer as one of the second planarization layer 126, the pixel defining layer 132, and the spacer layer 132′.

The first dam layer DML21 of the second dam portion DM2 may be disposed on the same layer as the first planarization layer 125. Each of the second dam layer DML22 and the third dam layer DML23 of the second dam portion DM2 may be disposed on the same layer as one of the second planarization layer 126, the pixel defining layer 132, and the spacer layer 132′.

According to embodiments, in the junction area JNA, the first sealing layer 141 may be in contact with the interlayer insulating layer 124.

The second sealing layer 142 may be limitedly disposed within an area surrounded by one or more dam portions DM disposed in the dam area DMA. As a result of these features, the third sealing layer 143 may be in contact with the first sealing layer 141 in a portion of the dam area DMA and the junction area JNA. For example, a junction structure of inorganic insulating materials formed by the interlayer insulating layer 124, the first sealing layer 141, and the third sealing layer 143 may be provided in the junction area JNA. As a result, permeation of moisture or oxygen through the organic insulating material may be blocked, thereby increasing the useful life of the display device.

According to embodiments, the circuit layer 120 of the display device 100 may further include a bending hole BDH disposed in the bending area BA and a bank BNK covering the bending hole BDH. The bending hole BDH may be used to remove the inorganic insulating materials of the circuit layer 120 that overlaps the bending area BA. Since the inorganic insulating material has relatively large stress when deformed into a bending shape, cracks or breakage of the inorganic insulating material due to bending stress may relatively easily occur. In order to prevent such a problem, the bending hole BDH disposed in the bending area BA may penetrate through the buffer layer 121, the first gate insulating layer 122, the second gate insulating layer 123, and the interlayer insulating layer 124, each of which includes the inorganic insulating materials.

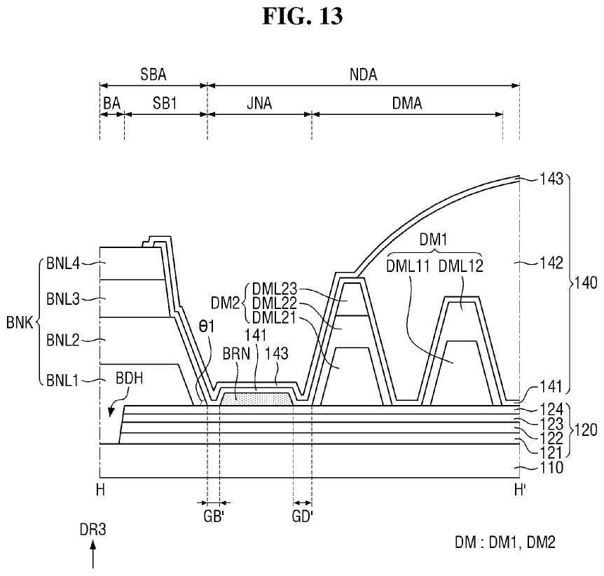

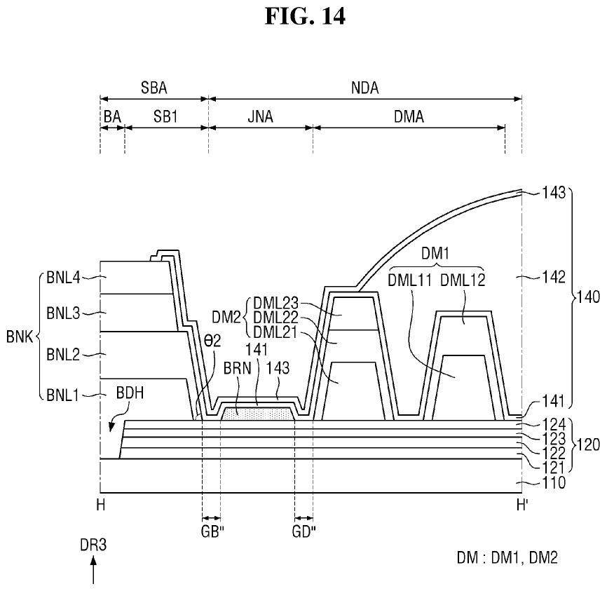

The bank BNK is used to fill the bending hole BDH and protect the lines in the bending area BA. As will be discussed in greater detail, for example, with reference to FIGS. 13 and 14, the bank BNK may be spaced from the junction area (and more specifically from branch portions of the power supply line) to improve operation of the display device. The bank BNK may include two or more bank layers BNL1, BNL2, BNL3, and BNL4, each of which includes an organic insulating material. As an example, the two or more bank layers may include a first bank layer BNL1 disposed on the same layer as the first planarization layer 125, a second bank layer BNL2 disposed on the same layer as the second planarization layer 126, a third bank layer BNL3 disposed on the same layer as the pixel defining layer 132, and a fourth bank layer BNL4 disposed on the same layer as the spacer layer 132′.

According to embodiments, the data supply lines DSPL and data pad lines DPDL may be disposed on the first gate conductive layer on the first gate insulating layer 122 or the second gate conductive layer on the second gate insulating layer 123.

The data line DL may be disposed on the second source/drain conductive layer on the first planarization layer 125. In this case, the data line DL may be electrically connected to the data supply line DSPL through a data supply connection hole DSCH penetrating through the first planarization layer 125 and the interlayer insulating layer 124.

The data bending line DBDL may be disposed on the second source/drain conductive layer on the first bank layer BNL1, which is the same layer as the first planarization layer 125. The data bending line DBDL may be electrically connected to the data supply line DSPL through a first data bending connection hole DBDCH1, and may be electrically connected to the data pad line DPDL through a second data bending connection hole DBDCH2.

As illustrated in FIG. 10, according to embodiments, the circuit layer 120 of the display device 100 may further include a first power bending line VDBDL disposed in the bending area BA and connected to the first power supply line VDSPL, and a first power pad line VDPDL disposed in the second sub-area SB2 and electrically connected to the first power bending line VDBDL. The first power pad line VDPDL may be connected to at least one signal pad that transmits the first power ELVDD among the signal pads SPD of the second sub-area SB2. For example, the first power supply line VDSPL may be electrically connected to the circuit board 300 through the first power bending line VDBDL, the first power pad line VDPDL, and at least one signal pad transmitting the first power ELVDD.

According to embodiments, the circuit layer 120 of the display device 100 may further include a second power bending line VSBDL disposed in the bending area BA and connected to the second power supply line VSSPL, and a second power pad line VSPDL disposed in the second sub-area SB2 and electrically connected to the second power bending line VSBDL. The second power pad line VSPDL may be connected to at least one signal pad that transmits the second power ELVSS among the signal pads SPD of the second sub-area SB2. For example, the second power supply line VSSPL may be electrically connected to the circuit board 300 through the second power bending line VSBDL, the second power pad line VSPDL, and at least one signal pad transmitting the second power ELVSS.

Referring to FIG. 12, the second power supply line VSSPL of the power supply line VSPL may extend to the first sub-area SB1 and may be connected to the second power bending line VSBDL of the bending area BA. The second power supply line VSSPL may be disposed on the first source/drain conductive layer on the interlayer insulating layer 124 or the second source/drain conductive layer on the first planarization layer 125.

Each of the first source/drain conductive layer and the second source/drain conductive layer may include a multilayer structure and be covered with the first planarization layer 125 and the second planarization layer 126, including a relatively thick organic insulating material in order to have relatively low line resistance. As an example, a portion of the second power supply line VSSPL may be disposed on the first source/drain conductive layer, and another portion of the second power supply line VSSPL may be disposed on the second source/drain conductive layer.

Like the data bending line DBDL, the second power bending line VSBDL may be disposed on the second source/drain conductive layer on the first bank layer BNL1, which is the same layer as the first planarization layer 125.

Like the data pad lines DPDL, the second power pad line VSPDL may be disposed on the first gate conductive layer on the first gate insulating layer 122 or the second gate conductive layer on the second gate insulating layer 123.

The second power bending line VSBDL may be electrically connected to the second power pad line VSPDL through the power bending connection hole VSBDCH.

Since the first power supply line VDSPL is similar to the second power supply line VSSPL, the first power bending line VDBDL is similar to the second power bending line VSBDL, and the second power pad line VSPDL is similar to the first power pad line VDPDL, redundant description will be omitted.

As illustrated in FIG. 11, according to embodiments, the non-display area NDA of the substrate 110 may include a dam area DMA surrounding the display area DA, and a junction area JNA surrounding the dam area DMA.

The junction area JNA may be disposed to be adjacent to the first sub-area SB1 of the sub-area SBA. A junction structure may be disposed in the junction area JNA. The junction structure may include inorganic material that is capable of blocking a permeation path of oxygen or moisture. For example, the first planarization layer 125, the second planarization layer 126, the pixel defining layer 132, and the spacer layer 132′, each including the organic insulating material, may be removed from the junction area JNA.

As the sub-connection portion SCN of the power supply line VSPL extends from the non-display area NDA to the sub-area SBA, the sub-connection portion SCN may overlap the dam area DMA and the junction area JNA. As described in greater detail below, one or more branch portions may extend from the sub-connection portion and be spaced from a bank BNK and the one or more dam area DMA.

However, since the first planarization layer 125, the second planarization layer 126, the pixel defining layer 132, and the spacer layer 132′ are removed from the junction area JNA, a portion of the sub-connection portion SCN of the power supply line VSPL overlapping the junction area JNA is not covered with the organic insulating material, but with the first sealing layer 141 and the third sealing layer 143 of the sealing layer 140.

In addition, the first source/drain conductive layer and the second source/drain conductive layer include a multilayer structure Reactivity to an etching material may differ depending on the metal materials included in the multilayer structure. However, the portion of the sub-connection portion SCN of the power supply line VSPL overlapping the junction area JNA is not protected by the second planarization layer 126, and thus may be exposed to the etching material during the arrangement of the anode electrode 131. As a result, the portion of the sub-connection portion SCN of the power supply line VSPL overlapping the junction area JNA may include an undercut structure of relatively large width.

Accordingly, it may be difficult to completely cover a side surface of the portion of the sub-connection portion SCN of the power supply line VSPL overlapping the junction area JNA with the first sealing layer 141. Therefore, a permeation path of oxygen or moisture that may exist due to a gap between the first sealing layer 141 and the side surface of the portion of the sub-connection portion SCN of the power supply line VSPL overlapping the junction area JNA.

Accordingly, as illustrated in FIGS. 10 and 11, according to embodiments, in order to prevent the permeation path of oxygen or moisture caused by the gap between the first sealing layer 141 and the side surface of the portion of the sub-connection portion SCN of the power supply line VSPL overlapping the junction area JNA, the power supply line VSPL may include a branch portion BRN disposed in the junction area JNA and protruding from at least one side of the sub-connection portion SCN.

In this way, since a circumference length of the portion of the sub-connection portion SCN of the power supply line VSPL overlapping the junction area JNA may be increased by the branch portion BRN by a circumference of the branch portion BRN, there may be a delay in or prevention of the permeation of oxygen or moisture into the display area DA through the gap between the side surface of the portion of the sub-connection portion SCN overlapping the junction area JNA and the first sealing layer 141.

FIGS. 13 and 14 are cross-sectional views taken along line H-H′ of FIG. 10 according to an embodiment.

As illustrated in FIGS. 13 and 14, according to embodiments, the branch portion BRN of the power supply line VSPL may be spaced apart from the bank BNK including the organic insulating material. The bank BNK is disposed with a relatively thick thickness on the interlayer insulating layer 124, and therefore, at an edge of the bank BNK, relatively high tensile force may be concentrated near the valley of the corner where the organic insulating material and the inorganic insulating material are bonded.

However, as in the embodiments, if the branch portion BRN of the power supply line VSPL is spaced apart from the bank BNK, the branch portion BRN may be relatively little affected by the tensile force around the bank BNK. Therefore, the lifting defect or corrosion defect of the branch portion BRN may be reduced or prevented.

The magnitude of the tensile force concentrated around the bank BNK may correspond to an angle θ1 of the side surface of the bank BNK with respect to the interlayer insulating layer 124. Accordingly, a distance GB′ at which the branch portion BRN is spaced apart from the bank BNK may be based on the angle θ1 of the side surface of the bank BNK with respect to the interlayer insulating layer 124.

As an example, the distance GB′ at which the branch portion BRN is spaced apart from the bank BNK may be about 2 μm or more. When the separation distance GB′ between the branch portion BRN and the bank BNK is less than 2 μm, the tensile force concentrated around the bank BNK may cause the lifting detect or corrosion detect of the branch portion BRN. In one embodiment, the distance GB′ at which the branch portion BRN is spaced apart from the bank BNK may be about 5 μm or more. In this way, most of the influence of the tensile force concentrated around the bank BNK on the branch portion BRN may be eliminated. The spacing distance between the branch portion BRN and the bank BNK may line in a different range of distances in another embodiment.

Meanwhile, as illustrated in FIG. 14, according to embodiments, as an angle θ2 (θ2>θ1) of the side surface of the bank BNK with respect to the interlayer insulating layer 124 increases, the influence of the tensile force concentrated around the bank BNK may increase. In this case, a distance GB″ (GB″>GB′) at which the branch portion BRN is spaced apart from the bank BNK may further increase.

Likewise, as illustrated in FIG. 13, according to embodiments, the branch portion BRN of the power supply line VSPL may be spaced apart from one or more dam portions DM including the organic insulating material. As a result, the lifting defect or corrosion defect of the branch portion BRN of the power supply line VSPL due to the tensile force concentrated around the dam portion DM may be reduced or prevented.

The magnitude of the tensile force concentrated around the dam portion DM may correspond to an angle of a side surface of the dam portion DM with respect to the interlayer insulating layer 124. Accordingly, a minimum distance GD′ at which the branch portion BRN is spaced apart from the dam portion DM may correspond to the angle of the side surface of the dam portion with respect to the interlayer insulating layer 124. As an example, the minimum distance GD′ at which the branch portion BRN is spaced apart from the dam portion DM may be about 2 μm or more. In one embodiment, the minimum distance GD′ at which the branch portion BRN is spaced apart from the dam portion DM may be about 5 μm or more. The spacing distance between the branch portion BRN and the dam portion DM may lie in a different range of distances in another embodiment.

As illustrated in FIG. 14, according to embodiments, as the angle of the side surface of the dam portion DM with respect to the interlayer insulating layer 124 increases, a distance GD″ (GD″>GD′) at which the branch portion BRN is spaced apart from the dam portion DM may further increase.

Meanwhile, as described above, according to embodiments, the power supply line VSPL includes the branch portion BRN disposed in the junction area JNA.

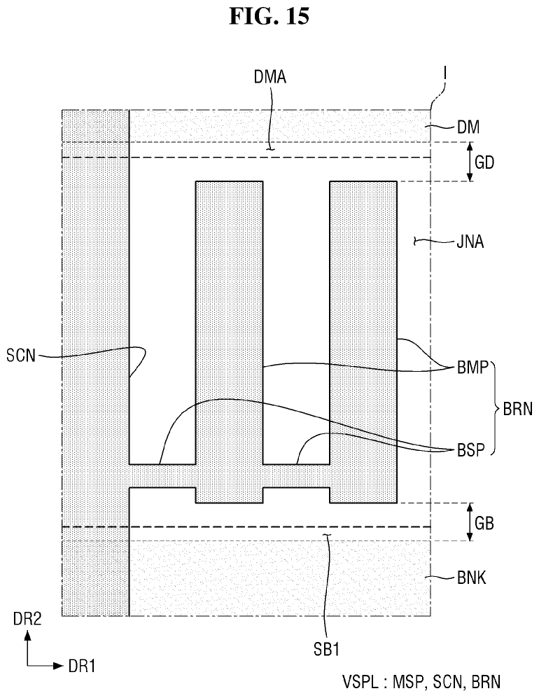

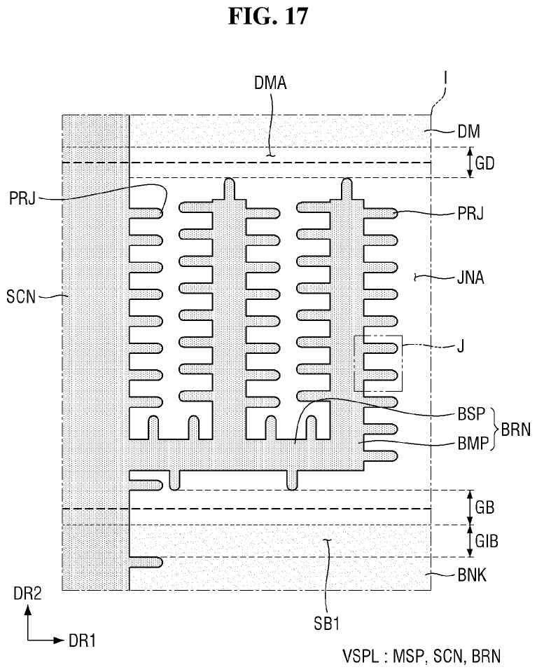

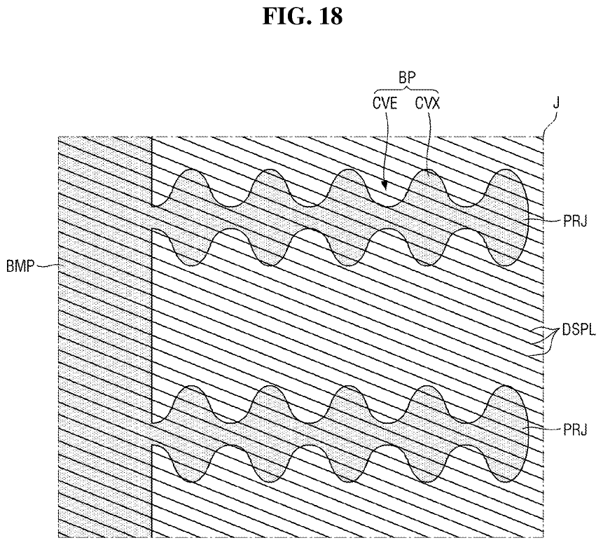

FIGS. 15, 16, and 17 show layout views illustrating portion I of FIG. 10 according to embodiments. FIG. 18 is an enlarged view illustrating portion J of FIG. 17 according to an embodiment. These figures show different embodiments of the features and formation of the branch portion BRN and sub-connection portion.

Referring to FIG. 15, the branch portion BRN according to embodiments may be disposed in the junction area JNA and protrude from one side of the sub-connection portion SCN. When the sub-area SBA protrudes from the main area MA in the second direction DR2, the sub-connection portion SCN may extend in the second direction DR2. In this case, the branch portion BRN may protrude from at least one side of the sub-connection portion SCN in the first direction DR1. In some embodiments, a branch portion may protrude from an opposing side of the sub-connection portion. The brank portions disposed on respective sides of the sub-connection portion may have the same arrangement or different arrangements of branch main portions, as described below.

For example, the branch portion BRN may include one or more branch main portions BMP extending parallel to the sub-connection portion SCN, and a branch sub-portion BSP connecting a sub-connection portion SCN and one or more branch main portions BMP.

The branch portion BRN may extend a circumference of a portion of the sub-connection portion SCN overlapping the junction area JNA, so as to lengthen the permeation path of oxygen or moisture toward the display area DA. Therefore, the branch sub-portion BSP may be disposed to be adjacent to the sub-area SBA so that oxygen or moisture passing through the side portion of the power supply line VSPL is not adjacent to the display area DA as much as possible.

According to embodiments, both ends of the branch main portion BMP in the second direction DR2 may be spaced apart from the bank BNK and the dam portion DM. A separation distance GB between the branch main portion BMP and the bank BNK may be about 2 μm or more, or about 5 μm or more. The separation distance may have different distance values in another embodiment. Likewise, a separation distance GD between the branch main portion BMP and the dam portion DM may be about 2 μm or more, or about 5 μm or more. The separation distance may lie in a different range of distances in another embodiment.

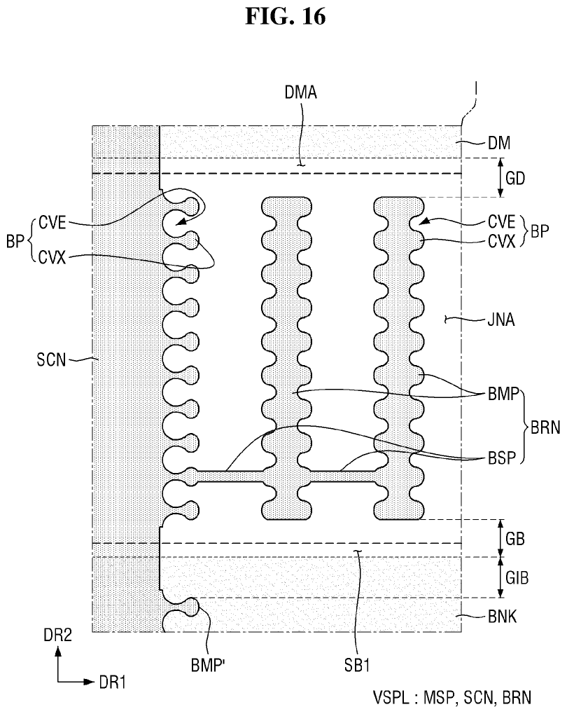

Referring to FIG. 16, the power supply line VSPL according to an embodiment is substantially the same as that of the embodiments illustrated in FIGS. 1 to 15, except that one edge of a portion of the sub-connection portion SCN overlapping the junction area JNA includes one or more irregularities BP, and an edge of the branch portion BRN includes one or more irregularities BP, and thus redundant descriptions are omitted below.

In one embodiment, the irregularities BP according to an embodiment may have a structure in which concave portions CVE and convex portions CVX are alternately arranged. According to an embodiment, one edge of the portion of the sub-connection portion SCN overlapping the junction area JNA may include irregularities BP arranged along the extension direction of the sub-connection portion SCN (e.g., the second direction DR2).

The irregularities BP disposed on one edge of the portion of the sub-connection portion SCN overlapping the junction area JNA may be spaced apart from each of the bank BNK and the dam portion DM. A minimum distance GB between the irregularities BP disposed on one edge of the portion of the sub-connection portion SCN overlapping the junction area JNA and the bank BNK may be about 2 μm or more, or about 5 μm or more. A minimum distance GB between the irregularities BP disposed on one edge of the portion of the sub-connection portion SCN overlapping the junction area JNA and the dam portion DM may be about 2 μm or more, or about 5 μm or more. The minimum distance may lie in a different range of distances in another embodiment. While the features located on the branch portions are described as irregularities, in other embodiments the surfaces of the branch portions may be formed to have features that have a regular geometry, e.g., triangular extensions, rectangular extensions or extensions having another type of geometry.

According to an embodiment, one edge of another portion of the sub-connection portion SCN overlapping the bank BNK may include at least one irregularity BP′. To reduce the impact from the tensile force concentrated around the bank BNK, at least one irregularity BP′ disposed on one edge of another portion of the sub-connection portion SCN overlapping the bank BNK may be spaced apart from the junction area JNA. A minimum distance GIB between at least one irregularity BP′ disposed on one edge of another portion of the sub-connection portion SCN overlapping the bank BNK and the junction area JNA may be, for example, about 2 μm or more, or about 5 μm or more.

According to an embodiment, the branch portion BRN may include irregularities BP disposed on an edge of the branch main portion BMP and arranged along an extension direction of the branch main portion BMP. The irregularities BP disposed on the edge of the branch portion BRN may be spaced apart from each of the bank BNK and the dam portion DM. A minimum distance GB between the irregularities BP disposed on the edge of the branch portion BRN and the bank BNK may be about 2 μm or more, or about 5 μm or more. A minimum distance GB between the irregularities BP disposed on the edge of the branch portion BRN and the dam portion DM may be about 2 μm or more, or about 5 μm or more. These values are given as examples and may correspond to different values in another embodiment.

Referring to FIG. 17, the power supply line VSPL according to an embodiment is substantially the same as that of the embodiments illustrated in FIGS. 1 to 15, except that one edge of the portion of the sub-connection portion SCN overlapping the junction area JNA includes one or more protrusions PRJ, and an edge of the branch portion BRN includes one or more protrusions PRJ, and thus redundant descriptions are omitted below.

The protrusions PRJ may be arranged along a circumference of a portion of the power supply line VSPL overlapping the junction area JNA. According to an embodiment, an extension direction of the protrusion PRJ may be perpendicular to a circumference of the power supply line VSPL. The protrusions PRJ disposed on an edge of the portion of the power supply line VSPL overlapping the junction area JNA may be spaced apart from each of the bank BNK and the dam portion DM.

A minimum distance GB between the protrusions PRJ disposed on the edge of the portion of the power supply line VSPL overlapping the junction area JNA and the bank BNK may be, for example, about 2 μm or more, or about 5 μm or more. In one embodiment, a minimum distance GD between the protrusions PRJ disposed on the edge of the portion of the power supply line VSPL overlapping the junction area JNA and the dam portion DM may be, for example, about 2 μm or more, or about 5 μm or more.

According to an embodiment, at least one protrusion PRJ may also be disposed on an edge of the portion of the sub-connection portion SCN overlapping the bank BNK. To reduce impact from the tensile force concentrated around the bank BNK, at least one protrusion PRJ disposed on the edge of the portion of the sub-connection portion SCN overlapping the bank BNK may be spaced apart from the junction area JNA. A minimum distance GIB between at least one protrusion PRJ disposed on the edge of the portion of the sub-connection portion SCN overlapping the bank BNK and the junction area JNA may be for example, about 2 μm or more, or about 5 μm or more.

As illustrated in FIG. 18, according to an embodiment, the power supply line VSPL may further include irregularities BP arranged along an edge of each of the protrusions PRJ. The irregularities BP may have a structure in which concave portions CVE and convex portions CVX are alternately arranged along the extension direction of the protrusion PRJ. Additionally, the power supply lines VSPL may overlap the data supply lines DSPL. In at least a portion of the junction area JNA, the data supply lines DSPL may extend in a predetermined (e.g., diagonal) direction intersecting the first direction DR1 and the second direction DR2.

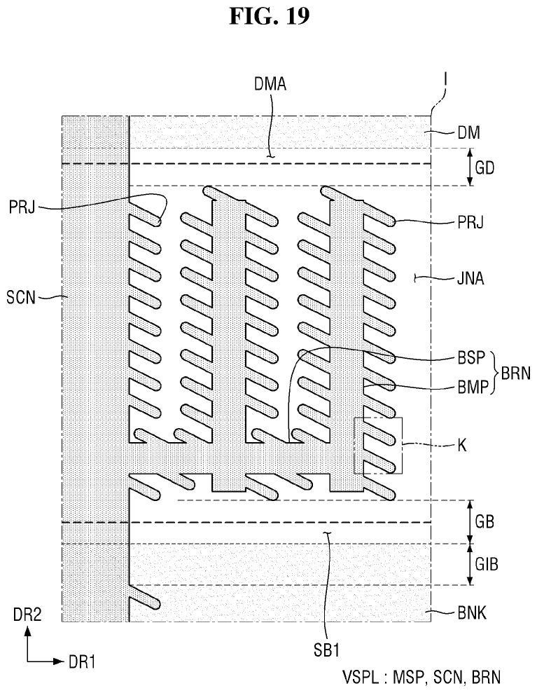

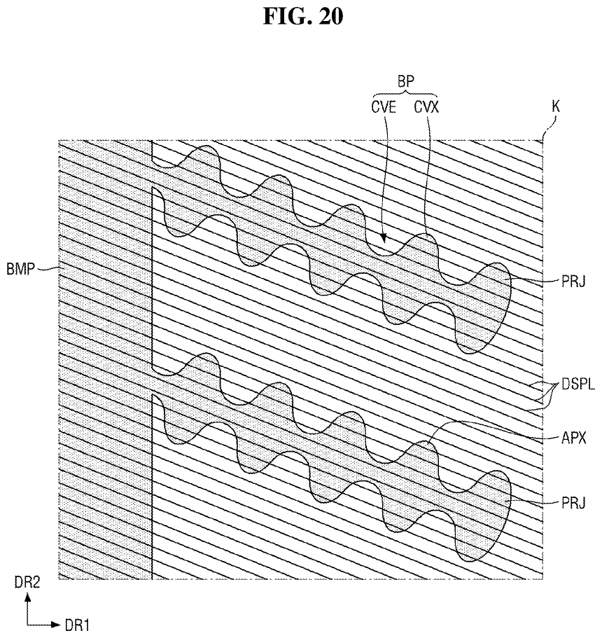

FIG. 19 is a layout view illustrating portion I of FIG. 10 according to an embodiment. FIG. 20 is an enlarged view illustrating portion K of FIG. 19 according to an embodiments.

Referring to FIGS. 19 and 20, the power supply line VSPL according to an embodiment is substantially the same as that of the embodiment illustrated in FIGS. 17 and 18, except that the protrusions PRJ extend in the diagonal direction intersecting the first direction DR1 and the second direction DR2, and thus redundant descriptions are omitted below.

According to an embodiment, the protrusions PRJ arranged along the circumference of a portion of the power supply line VSPL overlapping the junction area JNA may extend in parallel with the data supply line DSPL. As illustrated in FIG. 20, a midpoint APX of the convex portion CVX among the irregularities BP of each of the protrusions PRJ may overlap the spaced portion between the data supply lines DSPL. In one embodiment, a midpoint of the concave portion CVE among the irregularities BP of each of the protrusions PRJ may overlap the spaced portion between the data supply lines DSPL. In this way, the lifting defect or corrosion defect of the irregularities BP caused by the step difference depending on whether or not the data supply line DSPL is arranged may be reduced.

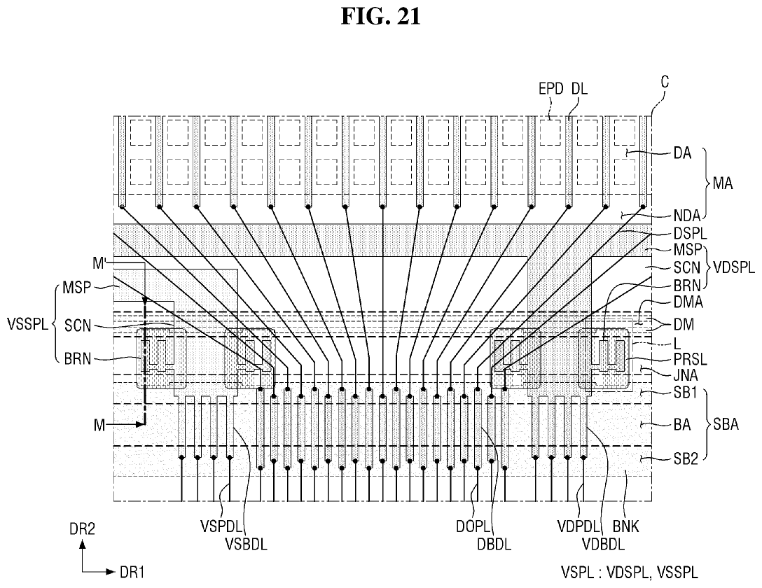

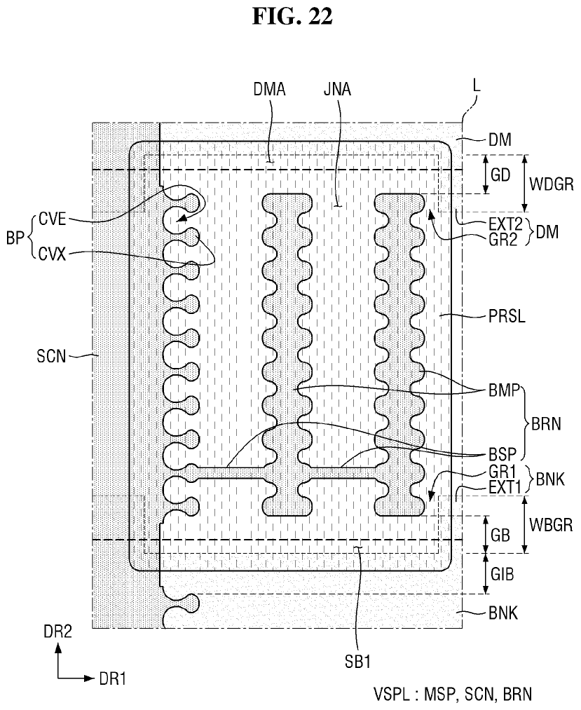

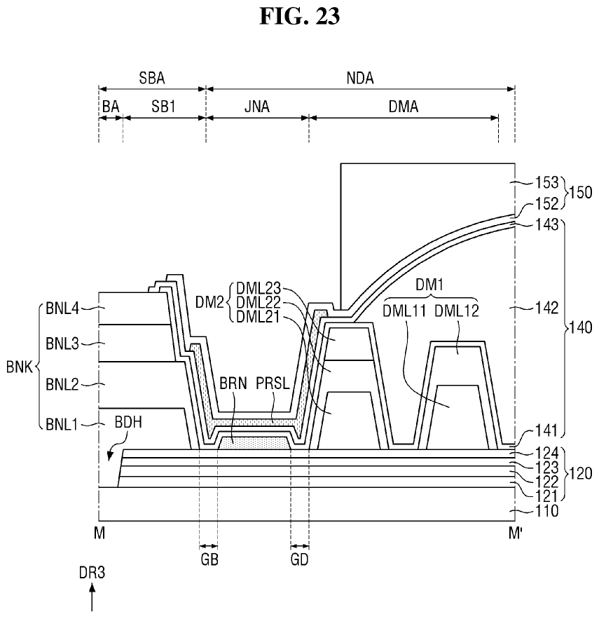

FIG. 21 is a layout view illustrating portion C of FIG. 4 according to an embodiment. FIG. 22 is a layout view illustrating portion L of FIG. 21 according to an embodiment. FIG. 23 is a cross-sectional view taken along line M-M′ of FIG. 21 according to an embodiment.

Referring to FIGS. 21 and 22, the display device 100 according to an embodiment is substantially the same as that of the embodiments of FIGS. 1 to 20, except that it further includes a pressing layer PRSL covering the branch portion BRN of the power supply line VSPL. Also, the bank BNK includes a first extension portion EXT1 and a first groove portion GR1, and one dam portion DM2 adjacent to the junction area JNA among the one or more dam portions DM includes a second extension portion EXT2 and a second groove portion GR2.

As illustrated in FIGS. 21 and 22, according to an embodiment, the bank BNK disposed in the sub-area SBA may include a first extension portion EXT1 extending to a portion of the junction area JNA adjacent to the sub-area SBA. Also, a first groove portion GR1 facing the branch portion BRN, spaced apart from the branch portion BRN, and recessed (e.g., concavely recessed) in a direction away from the branch portion BRN compared to the first extension portion EXT1. As an example, a minimum distance GB at which the first groove portion GR1 of the bank BNK is spaced apart from the branch portion BRN in the second direction DR2 may be about 2 μm or more, but may correspond to a different distance in another embodiment.

In addition, one dam portion DM2, adjacent to the junction area JNA among one or more dam portions DM arranged in the dam area DMA, may include a second extension portion EXT2 extending to another portion of the junction area JNA adjacent to the dam area DMA, and a second groove portion GR2 facing the branch portion BRN, spaced apart from the branch portion BRN, and concavely recessed in a direction away from the branch portion BRN compared to the second extension portion EXT2. As an example, a minimum distance GB at which the second groove portion GR2 of one dam portion DM2 is spaced apart from the branch portion BRN in the second direction DR2 may be about 2 μm or more, but may be a different distance in another embodiment.

In this way, since the bank BNK may be disposed to have a relatively wide width by the first extension portion EXT1, damage to the bank BNK, such as separation or collapse, may be reduced. Likewise, since one dam portion DM2 may be disposed to have a relatively wide width by the second extension portion EXT2, damage to one dam portion DM2, such as separation or collapse, may be reduced.

Additionally, since the branch portion BRN of the power supply line VSPL may be spaced apart from the bank BNK and one dam portion DM2 by the first groove portion GR1 of the bank BNK and the second groove portion GR2 of one dam portion DM2, the lifting defect or corrosion defect of the branch portion BRN may be reduced.

As illustrated in FIGS. 21 and 22, the pressing layer PRSL according to an embodiment may cover the branch portion BRN, and an edge of the first groove portion GR1 and an edge of the second groove portion GR2 disposed around the edge of the branch portion BRN.

Referring to FIG. 23, the pressing layer PRSL of the display device 100 according to an embodiment may be disposed on the branch portion BRN. Since the pressing layer PRSL may increase adhesion of the branch portion BRN, the lifting defect or corrosion defect of the branch portion BRN may be further reduced.

As an example, the pressing layer PRSL may be disposed on the same layer as the first touch conductive layer of the touch sensor layer 150 covered by the touch interlayer insulating layer 152. In this way, the deposition process and mask process for disposing the pressing layer PRSL may be excluded.

As noted above, organic light emitting material used in a display device may be quickly deteriorated due to moisture or oxygen. To prevent such deterioration, the display device may include a sealing layer that seals the light emitting elements. The sealing layer may be in contact with the inorganic insulating material of the circuit layer in a junction area surrounding a dam area in the non-display area.

For example, in at least a portion of the junction area, the organic insulating material may not be disposed. Accordingly, the lifting defect or corrosion defect of lines disposed in the junction area may easily occur. Since the lifting detect or corrosion defect of the lines cause a permeation path for moisture or oxygen, the quality and lifespan of the display device may be deteriorated.

In accordance with one or more embodiments, a display device is provided which is capable of improving quality and lifespan by reducing the lifting defect or corrosion defect of the lines disposed in the junction area.

Moreover, since the organic insulating material of each of the bank and dam portions is disposed with a relatively thick thickness on the inorganic insulating material in the junction area, a valley may occur at an edge where the organic insulating material and the inorganic insulating material are bonded to each other, and relatively high tensile force may be generated near the valley.

However, according to embodiments, the branch portion of the power supply line (spaced apart from each of the bank including the organic insulating material and the dam portion including the organic insulating material) is spaced apart from the valley occurring at the edge where the organic insulating material and the inorganic insulating material are bonded to each other. Therefore, since an influence of the tensile force near the valley on the branch portion of the power supply line may be reduced, the lifting defects and corrosion defects of the branch portion of the power supply line may be reduced. Accordingly, the quality and lifespan of the display device may be improved.

That is, according to embodiments, the branch portion may be spaced apart from each of the bank including the organic insulating material and the dam portion including the organic insulating material.

The effects of the present disclosure are not restricted to the one set forth herein. The above and other effects of the present disclosure will become more apparent to one of daily skill in the art to which the present disclosure pertains by referencing the claims. The embodiments may be combined to form additional embodiments.

What is claimed is:

1. A display device comprising:
a substrate;
a circuit layer disposed on the substrate;
an element layer disposed on the circuit layer; and
a sealing layer disposed on the element layer,
wherein the substrate includes a main area and a sub-area protruding from one side of the main area,
the main area includes a display area in which light emitting areas are arranged, and a non-display area disposed around the display area,
the non-display area includes a dam area in which one or more dam portions surrounding the display area are arranged, and a junction area surrounding the dam area,
the sub-area includes a bending area that is transformed into a bent shape, a first sub-area disposed between one side of the bending area and the main area and a second sub-area connected to the other side of the bending area,
the circuit layer includes a power supply line configured to transmit power,
the power supply line includes a main supply portion disposed in the non-display area, a sub-connection portion extending from the main supply portion to the sub-area, and a branch portion disposed in the junction area and protruding from one side of the sub-connection portion, and
the branch portion is spaced apart from a bank covering a bending hole of the bending area.

2. The display device of claim 1, wherein the branch portion is spaced apart from the at least one dam portion.

3. The display device of claim 2, wherein the bank includes:
a first extension portion extending to a portion of the junction area adjacent to the sub-area; and
a first groove portion facing the branch portion, spaced apart from the branch portion, and concavely recessed in a direction spaced apart from the branch portion compared to the first extension portion, and
one dam portion adjacent to the junction area among the one or more dam portions includes:
a second extension portion extending to another portion of the junction area adjacent to the dam area; and
a second groove portion facing the branch portion, spaced apart from the branch portion, and concavely recessed in a direction spaced apart from the branch portion compared to the second extension portion.

4. The display device of claim 3, further comprising:
a pressing layer disposed on the branch portion and covering the branch portion, an edge of the first groove portion, and an edge of the second groove portion.

5. The display device of claim 4, further comprising:
a touch sensor layer disposed on the sealing layer,
wherein the touch sensor layer includes:
a first touch conductive layer disposed on the sealing layer;
a touch interlayer insulating layer covering the first touch conductive layer;
a second touch conductive layer disposed on the touch interlayer insulating layer; and
a touch planarization layer covering the second touch conductive layer, and
the pressing layer is disposed on the same layer as the first touch conductive layer.

6. The display device of claim 2, wherein:
the branch portion includes one or more branch main portions extending parallel to the sub-connection portion, and a branch sub-portion connecting the sub-connection portion and the one or more branch main portions, and
the branch sub-portion is disposed to be adjacent to the sub-area.

7. The display device of claim 2, wherein:
one edge of a portion of the sub-connection portion overlapping the junction area includes irregularities arranged along an extension direction of the sub-connection portion,
an edge of the branch portion includes irregularities arranged along an extension direction of the branch portion, and
the irregularities are spaced apart from the bank and the at least one dam portion.

8. The display device of claim 2, wherein:
the power supply line further includes protrusions arranged along an edge of a portion of the sub-connection portion overlapping the junction area and an edge of the branch portion,
an edge of each of the protrusions has an irregularities, and
the protrusions are spaced apart from the bank and the at least one dam portion.

9. The display device of claim 2, wherein the power supply line includes a first power supply line and a second power supply line that are configured to respectively transmit first power and second power having different voltage levels.

10. A display device comprising:
a substrate;
a circuit layer disposed on the substrate;
an element layer disposed on the circuit layer; and
a sealing layer disposed on the element layer,
wherein the substrate includes a main area and a sub-area protruding from one side of the main area,
the main area includes a display area in which light emitting areas are disposed, and a non-display area disposed around the display area,
the non-display area includes a dam area in which one or more dam portions surrounding the display area are arranged, and a junction area surrounding the dam area,
the sub-area includes a bending area that is transformed into a bent shape, a first sub-area disposed between one side of the bending area and the main area, and a second sub-area connected to the other side of the bending area,
the element layer includes light emitting elements disposed in the light emitting areas,
the circuit layer includes light emitting pixel drivers electrically connected to the light emitting elements, and a power supply line that is configured to transmit power for driving the light emitting elements to the light emitting pixel drivers or the light emitting elements,
the power supply line includes a main supply portion disposed in the non-display area, a sub-connection portion extending from the main supply portion to the sub-area, and a branch portion disposed in the junction area and protruding from one side of the sub-connection portion,
one edge of a portion of the sub-connection portion overlapping the junction area includes irregularities arranged along an extension direction of the sub-connection portion,
an edge of the branch portion includes irregularities arranged along an extension direction of the branch portion, and
the irregularities are spaced apart from a bank covering a bending hole of the bending area.

11. The display device of claim 10, wherein the irregularities are spaced apart from the at least one dam portion.

12. The display device of claim 11, wherein:
the branch portion includes one or more branch main portions extending parallel to the sub-connection portion, a branch sub-portion connecting the sub-connection portion and the one or more branch main portions, and
the branch sub-portion is disposed to be adjacent to the sub-area.

13. The display device of claim 11, wherein the bank includes:
a first extension portion extending to a portion of the junction area adjacent to the sub-area; and
a first groove portion facing the branch portion, spaced apart from the branch portion, and concavely recessed in a direction spaced apart from the branch portion compared to the first extension portion, and
one dam portion adjacent to the junction area among the one or more dam portions includes:
a second extension portion extending to another portion of the junction area adjacent to the dam area; and
a second groove portion facing the branch portion, spaced apart from the branch portion, and concavely recessed in a direction spaced apart from the branch portion compared to the second extension portion.

14. The display device of claim 13, further comprising:
a pressing layer disposed on the branch portion and covering the branch portion, an edge of the first groove portion, and an edge of the second groove portion.

15. The display device of claim 14, further comprising:
a touch sensor layer disposed on the sealing layer,
wherein the touch sensor layer includes:
a first touch conductive layer disposed on the sealing layer;
a touch interlayer insulating layer covering the first touch conductive layer;
a second touch conductive layer disposed on the touch interlayer insulating layer; and
a touch planarization layer covering the second touch conductive layer, and
the pressing layer is disposed on the same layer as the first touch conductive layer.

16. A display device comprising:
a substrate;
a circuit layer disposed on the substrate;
an element layer disposed on the circuit layer; and
a sealing layer disposed on the element layer,
wherein the substrate includes a main area and a sub-area protruding from one side of the main area,
the main area includes a display area in which light emitting areas are disposed, and a non-display area disposed around the display area,
the non-display area includes a dam area in which one or more dam portions surrounding the display area are arranged, and a junction area surrounding the dam area,
the sub-area includes a bending area that is transformed into a bent shape, a first sub-area disposed between one side of the bending area and the main area, and a second sub-area connected to the other side of the bending area,
the element layer includes light emitting elements disposed in the light emitting areas,
the circuit layer includes light emitting pixel drivers electrically connected to the light emitting elements, and a power supply line that is configured to transmit power to drive the light emitting elements to the light emitting pixel drivers or the light emitting elements,
the power supply line includes a main supply portion disposed in the non-display area, a sub-connection portion extending from the main supply portion to the sub-area, a branch portion disposed in the junction area and protruding from one side of the sub-connection portion, and protrusions arranged along an edge of a portion of the sub-connection portion overlapping the junction area and an edge of the branch portion,
an edge of each of the protrusions has irregularities, and
the protrusions are spaced apart from the bank and the at least one dam portion.

17. The display device of claim 16, wherein the irregularities are spaced apart from the at least one dam portion.

18. The display device of claim 17, wherein the branch portion includes one or more branch main portions extending parallel to the sub-connection portion, a branch sub-portion connecting the sub-connection portion and the one or more branch main portions, and
the branch sub-portion is disposed to be adjacent to the sub-area.

19. The display device of claim 17, wherein the bank includes:
a first extension portion extending to a portion of the junction area adjacent to the sub-area; and
a first groove portion facing the branch portion, spaced apart from the branch portion, and concavely recessed in a direction spaced apart from the branch portion compared to the first extension portion, and
one dam portion adjacent to the junction area among the one or more dam portions includes:
a second extension portion extending to another portion of the junction area adjacent to the dam area; and
a second groove portion facing the branch portion, spaced apart from the branch portion, and concavely recessed in a direction spaced apart from the branch portion compared to the second extension portion.

20. The display device of claim 19, further comprising:
a pressing layer disposed on the branch portion and covering the branch portion, an edge of the first groove portion, and an edge of the second groove portion.

21. The display device of claim 20, further comprising:
a touch sensor layer disposed on the sealing layer,
wherein the touch sensor layer includes:
a first touch conductive layer disposed on the sealing layer;
a touch interlayer insulating layer covering the first touch conductive layer;
a second touch conductive layer disposed on the touch interlayer insulating layer; and
a touch planarization layer covering the second touch conductive layer, and
the pressing layer is disposed on the same layer as the first touch conductive layer.

22. A display device comprising:
a power supply line in a non-display area and including a sub-connection portion;
at least one dam in a circuit layer and surrounding a display area adjacent to the non-display area; and
a junction area between the at least one dam and a bending area,
wherein the at least one dam limits a sealing layer from passing into the junction area, and wherein the power supply line includes one or more branch portions located in the junction area and protruding from one side of the sub-connection portion, the one or more branch portions increasing a circumference length of the sub-connection portion of the power supply line.

23. The display device of claim 22, further comprising:
a bank covering a bending hole in the bending area,
wherein the one or more branch portions are spaced from the bank.

24. The display device of claim 22, wherein the one or more branch portions are spaced from the at least one dam.

25. The display device of claim 22, wherein the sub-connection portion includes irregularities.
